(19) United States
(12) Patent Application Publication
(10) Pub. No.: US 2017/0179162 A1
(43) Pub. Date: Jun. 22, 2017

(54) SEMICONDUCTOR DEVICE AND DISPLAY DEVICE

(71) Applicant: Sharp Kabushiki Kaisha, Osaka (JP)

(72) Inventors: Masao MORIGUCHI, Sakai City (JP); Yohsuke KANZAKI, Sakai City (JP); Yudai TAKANISHI, Sakai City (JP); Takatsugu KUSUMI, Sakai City (JP); Hiroshi MATSUKIZONO, Sakai City (JP)

(21) Appl. No.: 15/448,652

(22) Filed: Mar. 3, 2017

Related U.S. Application Data
(63) Continuation of application No. 13/996,033, filed on Jul. 10, 2013.

(30) Foreign Application Priority Data
Dec. 20, 2010 (JP) 2010-282919

(51) Int. Cl. H01L 27/12; H01L 29/786

(52) U.S. Cl. CPC H01L 27/124; H01L 29/7869; H01L 29/78606; H01L 27/1248; H01L 27/1255; H01L 27/1225; G02F 1/1368

(57) ABSTRACT

A semiconductor device (100) according to the present invention is a semiconductor device with a thin-film transistor (10), and includes: a gate electrode (62) which has been formed on a substrate (60) as a part of the thin-film transistor (10); a gate insulating layer (66) which has been formed on the gate electrode (62); an oxide semiconductor layer (68) which has been formed on the gate insulating layer (66); a source electrode (70s) and a drain electrode (70d) which have been formed on the oxide semiconductor layer (68); a protective layer (72) which has been formed on the oxide semiconductor layer (68), the source electrode (70s) and the drain electrode (70d); an oxygen supplying layer (74) which has been formed on the protective layer (72); and an anti-diffusion layer (78) which has been formed on the oxygen supplying layer (74).

### TECHNICAL FIELD

The present invention relates to a semiconductor device and display device, each including a thin-film transistor.

### BACKGROUND ART

An active-matrix-addressed liquid crystal display device or an organic EL (electroluminescence) display device generally includes a substrate on which thin-film transistors (which will also be referred to herein as “TFTs”) are provided as switching elements for respective pixels (such a substrate will be referred to herein as a “TFT substrate”), a counter substrate on which a counter electrode, color filters and other members are arranged, and a light modulating layer such as a liquid crystal layer which is interposed between the TFT substrate and the counter substrate.

On the TFT substrate, arranged are a plurality of source lines, a plurality of gate lines, a plurality of TFTs which are located at their intersections, pixel electrodes to apply a voltage to the light modulating layer such as a liquid crystal layer, storage capacitor lines, storage capacitor electrodes, and so on.

A configuration for a TFT substrate is disclosed in Patent Document No. 1, for example. Hereinafter, the configuration of the TFT substrate disclosed in Patent Document No. 1 will be described with reference to the accompanying drawings.

FIG. 30(a) is a schematic plan view generally illustrating what the TFT substrate is like. FIG. 30(b) is an enlarged plan view illustrating a single pixel of the TFT substrate. And FIG. 31 is a cross-sectional view illustrating the TFT and terminal portion of the semiconductor device shown in FIG. 30.

As shown in FIG. 30(a), the TFT substrate includes a plurality of gate lines 2016 and a plurality of source lines 2017. Each of multiple regions 2021 surrounded with these lines 2016 and 2017 defines a “pixel”. On the area 2040 of the TFT substrate other than its area where pixels are arranged (i.e., its display area), arranged are a plurality of connecting portions 2041 which connect those gate lines 2016 and source lines 2017 to their drivers. These terminal portions 2041 together form a terminal section to be connected to an external line.

As shown in FIGS. 30(b) and 31, a pixel electrode 2020 is arranged so as to cover each region 2021 to define a pixel. Also, a TFT has been formed in each region 2021. The TFT includes a gate electrode G, a gate insulating film 2025, 2026 which covers the gate electrode G, a semiconductor layer 2019 stacked on the gate insulating film 2026, and source and drain electrodes S and D which are connected to both ends of the semiconductor layer 2019. The TFT is covered with a protective film 2028. The gap between the protective film 2028 and the pixel electrode 2020 is filled with an interlevel dielectric film 2029. The source electrode S of the TFT is connected to one of the source lines 2017 and its gate electrode G is connected to one of the gate lines 2016. And its drain electrode D is connected to the pixel electrode 2020 in a contact hole 2030.

Also, a storage capacitor line 2018 is arranged parallel to each gate line 2016, and is connected to a storage capacitor. In this case, the storage capacitor is comprised of a storage capacitor electrode 2018b which is made of the same conductive film as the drain electrode D, another storage capacitor electrode 2018a which is made of the same conductive film as the gate line 2016, and a gate insulating film 2026 interposed between them.

Each connecting section 2041 extended from each gate line 2016 or source line 2017 is not covered with the gate insulating film 2025, 2026 or the protective film 2028. Instead, a connector line 2044 is arranged in contact with the upper surface of the connecting section 2041. In this manner, electrical connection is established between the connecting section 2041 and the connector line 2044.

Also, as shown in FIG. 31, in the liquid crystal display device, the TFT substrate is arranged to face the substrate 2014 on which the counter electrode and color filters have been formed with a liquid crystal layer 2015 interposed between them.

In fabricating such a TFT substrate, the region 2021 to define a pixel (which will be sometimes referred to herein as a “pixel section”) and a terminal section are suitably formed by the same process in order to minimize an increase in the number of masks to use or the number of processing steps to perform.

To fabricate such a TFT substrate, portions of the gate insulating film 2025, 2026 and protective film 2028 need to be etched away from a terminal arrangement region 2040 and portions of the gate insulating film 2025 and the protective film 2028 need to be etched away from a region where a storage capacitor is going to be formed. Patent Document No. 1 discloses making an interlevel dielectric film 2029 of an organic insulating film and etching the insulating film 2025, 2026 and the protective film 2028 using that interlevel dielectric film 2029 as a mask.

Recently, people have proposed that a channel layer be formed for a TFT using an oxide semiconductor film of IGZO (InGaZnOₓ), for example, instead of a silicon semiconductor film. Such a TFT will be referred to herein as an “oxide semiconductor TFT”. Since an oxide semiconductor has higher mobility than amorphous silicon, the oxide semiconductor TFT can operate at higher speeds than an amorphous silicon TFT. Also, such an oxide semiconductor film can be formed by a simpler process than a polysilicon film, and therefore, is applicable to even a device that needs to cover a large area.

Patent Document No. 2 discloses an example of such an oxide semiconductor TFT. Meanwhile, Patent Document No. 3 discloses an example of a field effect transistor including an active layer made of an amorphous oxide semiconductor.

According to Patent Document No. 3, before an amorphous oxide semiconductor layer is formed on a substrate, the surface of the substrate is either irradiated with an ultraviolet ray in an ozone ambient or plasma or cleaned with hydrogen peroxide to form the amorphous oxide semiconductor layer as intended. Patent Document No. 3 also says that the process step of forming an active layer including an amorphous oxide is performed within an ambient such as an ozone gas or a nitrogen oxide gas and that after an amorphous oxide has been deposited on the substrate, a heat treatment is carried out at a higher temperature than the deposition temperature of the amorphous oxide.

### CITATION LIST

### Patent Literature

Patent Document No. 1: Japanese Laid-Open Patent Publication No. 2008-170664
Patent Document No. 2: Japanese Laid-Open Patent Publication No. 2003-298062
Patent Document No. 3: Japanese Laid-Open Patent Publication No. 2006-165531

### SUMMARY OF INVENTION

### Technical Problem

In an oxide semiconductor TFT, however, during the manufacturing process of the TFT (e.g., during a heat treatment process step), oxygen deficiencies could be produced to produce carrier electrons and eventually generate unnecessary OFF-state current, which is a problem. In addition, in the process step of etching the source and drain electrodes and in the process step of depositing an insulating layer on the source and drain electrodes, the underlying oxide semiconductor layer could be subject to a reduction reaction and other kinds of damage, which is also a problem.

The present inventors discovered via experiments that in an oxide semiconductor TFT in which an oxide semiconductor layer contacted with the underlying gate insulating layer or the overlying protective layer, defect levels due to the presence of oxygen deficiencies would be produced easily inside the oxide semiconductor layer or in the vicinity of the interface between the oxide semiconductor layer and the insulating layer or the protective layer, thus causing a decline in the performance or reliability of the TFT and varying their quality significantly from one product to another.

Patent Document No. 3 proposes that after an amorphous oxide has been deposited, a heat treatment be carried out at a higher temperature than the deposition temperature of the amorphous oxide in order to obtain a transistor with good performance. Even when such a method is adopted, however, those defect levels to be caused due to the presence of oxygen deficiencies cannot be reduced and it is difficult to realize good TFT performance.

The present inventors perfected our invention in order to overcome the problems described above by providing a semiconductor device with excellent TFT performance with such defects which have been caused in the oxide semiconductor layer of the oxide semiconductor TFT reduced. Another object of the present invention is to provide a high-performance display device including such a semiconductor device as its TFT substrate.

### Solution to Problem

A semiconductor device according to the present invention is a semiconductor device with a thin-film transistor, and includes: a gate electrode which has been formed on a substrate as a part of the thin-film transistor; a gate insulating layer which has been formed on the gate electrode; an oxide semiconductor layer which has been formed on the gate insulating layer; a source electrode and a drain electrode which are arranged on the oxide semiconductor layer as parts of the thin-film transistor; a protective layer which has been formed on the oxide semiconductor layer and the source and drain electrodes; an oxygen supplying layer which has been formed on the protective layer; and an anti-diffusion layer which has been formed on the oxygen supplying layer.

In one embodiment, the oxygen supplying layer is made of a material including water (H₂O), an OR group, or an OH group.

In one embodiment, the oxygen supplying layer is made of an acrylic resin, an SOG material, a silicone resin, an ester polymer resin, or a resin including a silanol group, a CO—OR group or an Si—OH group.

In one embodiment, the oxygen supplying layer has a thickness of 500 nm to 3500 nm.

In one embodiment, the anti-diffusion layer is made of silicon dioxide, silicon nitride, or silicon oxynitride.

In one embodiment, the anti-diffusion layer has a thickness of 50 nm to 500 nm.

In one embodiment, the protective layer is made of silicon dioxide or silicon nitride.

In one embodiment, the semiconductor device includes: a lower wiring which is made of the same material as the gate electrode; an upper wiring which is made of the same material as the source and drain electrodes; and a connecting portion which connects the upper and lower wirings together. In the connecting portion, the upper and lower wirings are connected together through a contact hole which runs through the gate insulating layer.

In one embodiment, in the connecting portion, the contact hole has been cut to run through the oxide semiconductor layer and the gate insulating layer, and the upper and lower wirings are connected together through the contact hole.

In one embodiment, the connecting portion includes: an insulating layer which has been formed on the lower wiring; the upper wiring which has been formed on the insulating layer; the protective layer which has been formed on the upper wiring; the oxygen supplying layer which has been formed on the protective layer; the anti-diffusion layer which has been formed on the oxygen supplying layer; and a conductive layer which has been formed on the anti-diffusion layer. A contact hole has been cut to run through the insulating layer, upper wiring, protective layer, oxygen supplying layer and anti-diffusion layer of the connecting portion. And the lower and upper wirings are electrically connected together through the conductive layer that has been deposited in the contact hole.

In one embodiment, the connecting portion includes: an insulating layer which has been formed on the lower wiring; the upper wiring which has been formed on the insulating layer; the protective layer which has been formed on the upper wiring; the oxygen supplying layer which has been formed on the protective layer; the anti-diffusion layer which has been formed on the oxygen supplying layer; and a conductive layer which has been formed on the anti-diffusion layer. A first contact hole has been cut to run through the protective layer, oxygen supplying layer and anti-diffusion layer of the connecting portion. A second contact hole has been cut to run through the insulating layer, protective layer, oxygen supplying layer and anti-diffusion layer of the connecting portion. The upper wiring and the conductive layer are electrically connected together inside the first contact hole. And the lower wiring and the conductive layer are electrically connected together inside the second contact hole.

In one embodiment, the semiconductor device includes a storage capacitor which includes: a storage capacitor electrode which is made of the same material as the gate electrode; the anti-diffusion layer which has been formed on and in contact with the storage capacitor electrode; and a storage capacitor counter electrode which has been formed on the anti-diffusion layer.

In one embodiment, the semiconductor device includes a storage capacitor which includes: a storage capacitor electrode which is made of the same material as the gate electrode; a first conductive layer which has been formed on and in contact with the storage capacitor electrode; the anti-diffusion layer which has been formed on and in contact with the first conductive layer; and a storage capacitor counter electrode which has been formed on the anti-diffusion layer.

In one embodiment, the semiconductor device includes a storage capacitor which includes: a storage capacitor electrode which is made of the same material as the gate electrode; the oxide semiconductor layer which has been formed on and in contact with the storage capacitor electrode; the anti-diffusion layer which has been formed on and in contact with the oxide semiconductor layer on the storage capacitor electrode; and a storage capacitor counter electrode which has been formed on the anti-diffusion layer.

A display device according to the present invention includes a semiconductor device according to any of the embodiments described above, and includes a pixel electrode which has been formed on the anti-diffusion layer. The pixel electrode is connected to the drain electrode through a contact hole that runs through the protective layer, the oxygen supplying layer, and the anti-diffusion layer.

Another display device according to the present invention is a fringe field type display device including a semiconductor device according to any of the embodiments described above. The display device includes: a lower electrode which is arranged between the oxygen supplying layer and the anti-diffusion layer; and an upper electrode which is arranged on the anti-diffusion layer and connected to the drain electrode of the thin-film transistor.

In one embodiment, that another display device includes a common line which is made of the same material as the gate electrode. The common line and the lower electrode are connected together through a contact hole that runs through the gate insulating layer, the protective layer, and the oxygen supplying layer.

In one embodiment of a semiconductor device according to the present invention, the protective layer has a density of 1.9 to 2.2 g/cm³.

In one embodiment of a semiconductor device according to the present invention, the protective layer is comprised of a first protective layer which has been formed on the oxide semiconductor layer and the source and drain electrodes, and a second protective layer which has been formed on the first protective layer and which has a lower density than the first protective layer.

In one embodiment, the first protective layer has a density of 2.1 to 2.4 g/cm³ and the second protective layer has a density of 1.9 to 2.2 g/cm³.

In one embodiment, the semiconductor device of the present invention includes an etch stopper layer which has been formed between the oxide semiconductor layer and the source and drain electrodes.

Another display device according to the present invention includes a semiconductor device according to any of these embodiments.

Another semiconductor device according to the present invention is a semiconductor device with a thin-film transistor, and includes: a gate electrode which has been formed on a substrate as a part of the thin-film transistor; a gate insulating layer which has been formed on the gate electrode; an oxide semiconductor layer which has been formed on the gate insulating layer; a source electrode and a drain electrode which are arranged on the oxide semiconductor layer as parts of the thin-film transistor; and an oxygen supplying layer which has been formed on the oxide semiconductor layer and the source and drain electrodes to contact with the oxide semiconductor layer.

In one embodiment, the semiconductor device includes a protective layer which is arranged between the oxide semiconductor layer, the source and drain electrodes, and the oxygen supplying layer, and the oxygen supplying layer contacts with the oxide semiconductor layer through a contact hole which has been cut through the protective layer.

In one embodiment, the semiconductor device includes an anti-diffusion layer which has been formed on the oxygen supplying layer.

In one embodiment, the semiconductor device includes an etch stopper layer which has been formed between the oxide semiconductor layer and the source and drain electrodes.

Another semiconductor device according to the present invention is a semiconductor device with a thin-film transistor, and includes: a gate electrode which has been formed on a substrate as a part of the thin-film transistor; a gate insulating layer which has been formed on the gate electrode; a source electrode and a drain electrode which have been formed on the gate insulating layer as parts of the thin-film transistor; an oxide semiconductor layer which has been formed on the gate insulating layer and the source and drain electrodes; a protective layer which has been formed on the oxide semiconductor layer; and an oxygen supplying layer which has been formed on the protective layer.

Another semiconductor device according to the present invention is a top gate type semiconductor device with a thin-film transistor, and includes: a source electrode and a drain electrode which have been formed on a substrate as parts of the thin-film transistor; an oxide semiconductor layer which has been formed on the source and drain electrodes; an insulating layer which has been formed on the oxide semiconductor layer and the source and drain electrodes; a gate electrode which has been formed on the insulating layer as a part of the thin-film transistor; an oxygen supplying layer which has been formed on the insulating layer and the gate electrode; and an anti-diffusion layer which has been formed on the oxygen supplying layer.

Another display device according to the present invention includes a semiconductor device according to any of the embodiments described above.

### Advantageous Effects of Invention

According to the present invention, H₂O, an OR group, or an OH group is supplied from the oxygen supplying layer to the oxide semiconductor layer, and therefore, a high-performance semiconductor device including an oxide semiconductor layer, of which the defects have been repaired more perfectly, can be obtained. In addition, according to the present invention, a high-reliability semiconductor device, of which the characteristic varies much less significantly from one TFT to another, can also be obtained. Furthermore, according to the present invention, a display device with an oxide semiconductor TFT having excellent characteristics realizes a higher display quality.

### BRIEF DESCRIPTION OF DRAWINGS

FIG. 1 A perspective view schematically illustrating a configuration for a liquid crystal display device 1000 as a first embodiment of the present invention.

FIG. 2 A plan view schematically illustrating a configuration for the TFT substrate (semiconductor device 100) of the liquid crystal display device 1000.

FIG. 3 A plan view schematically illustrating the configuration of the TFT substrate 100 in its display area DA.

FIG. 4 A cross-sectional view schematically illustrating the configuration of a TFT 10 according to the first embodiment.

FIG. 5 A cross-sectional view schematically illustrating the configuration of, and the effects achieved by, the TFT 10 of the first embodiment.

FIGS. 6 (a) and (b) are graphs showing what effects are achieved by the TFT 10, wherein (a) shows the voltage-current characteristics of TFTs with an oxygen supplying layer, while (b) shows the voltage-current characteristics of TFTs with no oxygen supplying layer.

FIG. 7 (a) through (d) are cross-sectional views schematically illustrating respective manufacturing process steps to fabricate the TFT substrate 100.

FIG. 8 (e) through (g) are cross-sectional views schematically illustrating respective manufacturing process steps to fabricate the TFT substrate 100.

FIG. 9 A cross-sectional view schematically illustrating a first exemplary configuration for a connecting portion in which upper and lower wirings are connected together on the TFT substrate 100.

FIG. 10 A cross-sectional view schematically illustrating a second exemplary configuration for a connecting portion on the TFT substrate 100.

FIG. 11 A cross-sectional view schematically illustrating a third exemplary configuration for a connecting portion on the TFT substrate 100.

FIG. 12 A cross-sectional view schematically illustrating the configuration of a TFT substrate 100 as a second embodiment of the present invention.

FIG. 13 A cross-sectional view schematically illustrating the configuration of a TFT substrate 100 as a first modified example of the second embodiment.

FIG. 14 A cross-sectional view schematically illustrating the configuration of a TFT substrate 100 as a second modified example of the second embodiment.

FIG. 15 A plan view schematically illustrating a configuration for a pixel 50 of a TFT substrate 100 as a third embodiment of the present invention.

FIG. 16 A cross-sectional view schematically illustrating the configuration of a TFT substrate 100 according to the third embodiment.

FIG. 17 A plan view schematically illustrating a configuration for a pixel 50 as a modified example of the third embodiment.

FIG. 18 A cross-sectional view schematically illustrating the configuration of a TFT 10 as a fourth embodiment of the present invention.

FIG. 19 A cross-sectional view schematically illustrating the configuration of a TFT 10 as a fifth embodiment of the present invention.

FIG. 20 A cross-sectional view schematically illustrating the configuration of a TFT 10 as a sixth embodiment of the present invention.

FIG. 21 A cross-sectional view schematically illustrating the configuration of a TFT 10 as a seventh embodiment of the present invention.

FIG. 22 A graph showing the voltage-current characteristics of the TFT 10 of the seventh embodiment to indicate what effects are achieved by the TFT 10.

FIG. 23 A cross-sectional view schematically illustrating the configuration of a TFT 10 as an eighth embodiment of the present invention.

FIG. 24 A cross-sectional view schematically illustrating the configuration of a TFT 10 as a ninth embodiment of the present invention.

FIG. 25 A cross-sectional view schematically illustrating the configuration of a TFT 10 as a tenth embodiment of the present invention.

FIG. 26 A cross-sectional view schematically illustrating the configuration of a TFT 10 as an eleventh embodiment of the present invention.

FIG. 27 A cross-sectional view schematically illustrating the configuration of a TFT 10 as a twelfth embodiment of the present invention.

FIG. 28 A cross-sectional view schematically illustrating the configuration of a TFT 10 as a thirteenth embodiment of the present invention.

FIG. 29 A cross-sectional view schematically illustrating the configuration of an organic EL display device 1002 as a fourteenth embodiment of the present invention.

FIG. 30 (a) is a schematic plan view generally illustrating what a conventional TFT substrate is like. (b) is an enlarged plan view illustrating a single pixel of the TFT substrate shown in FIG. 30(a).

FIG. 31 A cross-sectional view illustrating the TFT and terminal portion of the conventional TFT substrate shown in FIG. 30.

### DESCRIPTION OF EMBODIMENTS

Hereinafter, embodiments of a display device and semiconductor device according to the present invention will be described with reference to the accompanying drawings. However, the present invention is in no way limited to the specific embodiments to be described below. A semiconductor device according to the present invention is a TFT substrate with an oxide semiconductor TFT, which may be used in any of various kinds of display devices and electronic devices. In the following description of embodiments, the semiconductor device is supposed to be a TFT substrate for a display device which includes an oxide semiconductor TFT as its switching element.

### Embodiment 1

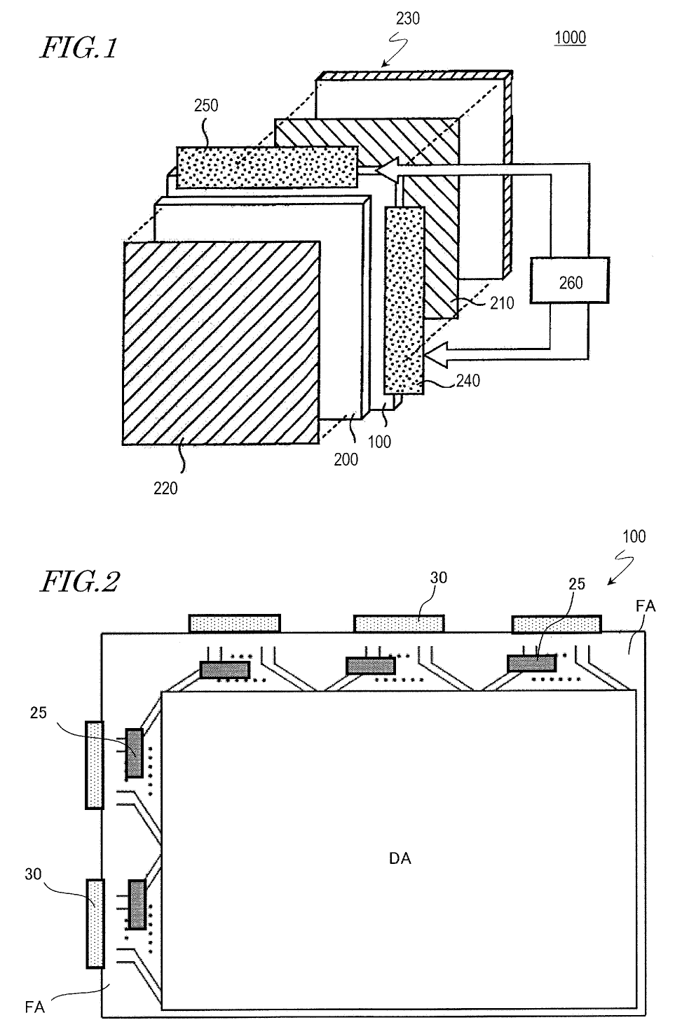

FIG. 1 is a perspective view schematically illustrating a configuration for a liquid crystal display device 1000 as an embodiment of the present invention.

As shown in FIG. 1, this liquid crystal display device 1000 includes a TFT substrate (semiconductor device) 100 and a counter substrate 200 which face each other with a liquid crystal layer interposed between them, polarizers 210 and 220, which are arranged outside of the TFT substrate 100 and the counter substrate 200, respectively, and a backlight unit 230 which emits light for display toward the TFT substrate 100. On the TFT substrate 100, arranged are a scan line driver 240 which drives a plurality of scan lines (gate bus lines) and a signal line driver 250 which drives a plurality of signal lines (data bus lines). The scan line driver 240 and the signal line driver 250 are connected to a controller 260 which is arranged either inside or outside of the TFT substrate 100. Under the control by the controller 260, the scan line driver 240 supplies a scan signal to turn ON/OFF TFTs to those scan lines, and the signal line driver 250 supplies a display signal (which is a voltage to be applied to the pixel electrode 20 shown in FIG. 3) to those signal lines.

The counter substrate 200 includes color filters and a common electrode. If a display operation is conducted in the three primary colors, the color filters include R (red), G (green) and B (blue) filters, each of which is arranged to face a pixel. Optionally, the counter substrate 200 may also be configured to carry out a display operation in four or more primary colors. The common electrode is arranged to cover a plurality of pixel electrodes 20 with the liquid crystal layer interposed between them. Liquid crystal molecules that are located between the common electrode and each pixel electrode 20 get aligned according to a potential difference created between those electrodes, thereby conducting a display operation.

FIG. 2 is a plan view schematically illustrating a configuration for the TFT substrate 100, and FIG. 3 is a plan view schematically illustrating the configuration of the TFT substrate 100 in its display area DA.

As shown in FIG. 2, the TFT substrate 100 has the display area DA and a peripheral area (frame area) FA which surrounds the display area DA. In the peripheral area FA, the scan line driver 240 and signal line driver 250 shown in FIG. 1, electrical elements that form a voltage supply circuit and other components are arranged by the COG (chip on glass) method. The TFTs, diodes and other electrical elements in the peripheral area FA and the TFTs in the display area DA may be fabricated by performing the same series of manufacturing process steps. Furthermore, terminal portions 30, to which an external element such as an FPC (flexible printed circuit) is attached, are arranged around the outer edge of the peripheral area FA. In addition, connecting portions 25 which electrically connect upper wirings such as the signal lines and lower wirings such as the scan lines are arranged in the peripheral area FA.

Although not shown, a plurality of connecting lines are arranged in the boundary between the display area DA and the peripheral area FA. Each signal line 12 is electrically connected to one of the connecting lines via its associated connecting portion. Through those connecting portions, the signal lines 12 as upper wirings are connected to the connecting lines as lower wirings.

As shown in FIG. 3, in the display area DA, a plurality of pixels 50 are arranged in matrix, and a plurality of scan lines 14 and a plurality of signal lines 12 run to cross each other at right angles. A portion of the scan line 14 functions as the gate electrode of the TFT 10. A thin-film transistor (TFT) 10 as an active component is arranged for each pixel 50 in the vicinity of each of the intersections between the scan lines 14 and the signal lines 12. In each of those pixels 50, a pixel electrode 20 made of ITO (indium tin oxide) is arranged and electrically connected to the drain electrode of its associated TFT 10. Also, a storage capacitor line (which will be sometimes referred to herein as a “Cs line”) 16 runs parallel to, and between, two adjacent ones of the scan lines 14.

In each pixel 10, a storage capacitor (Cs) 18 has been formed, and a portion of the storage capacitor line 16 functions as the storage capacitor electrode (i.e., lower electrode) of the storage capacitor 18. This storage capacitor electrode, a storage capacitor counter electrode (upper electrode) and a layer arranged between the two electrodes together form the storage capacitor 18. The drain electrode of each TFT 10 is connected to the storage capacitor counter electrode of its associated storage capacitor. And the storage capacitor counter electrode is connected to its associated pixel electrode 20 through a contact hole which has been cut through an interlayer insulating layer. The gate electrodes of the respective TFTs 10, the scan lines 14, the storage capacitor lines 16 and the storage capacitor electrodes are basically formed of the same material in the same process step. Likewise, the source and drain electrodes of the TFTs 10, the signal lines 12 and the storage capacitor counter electrodes are also basically formed of the same material in the same process step.

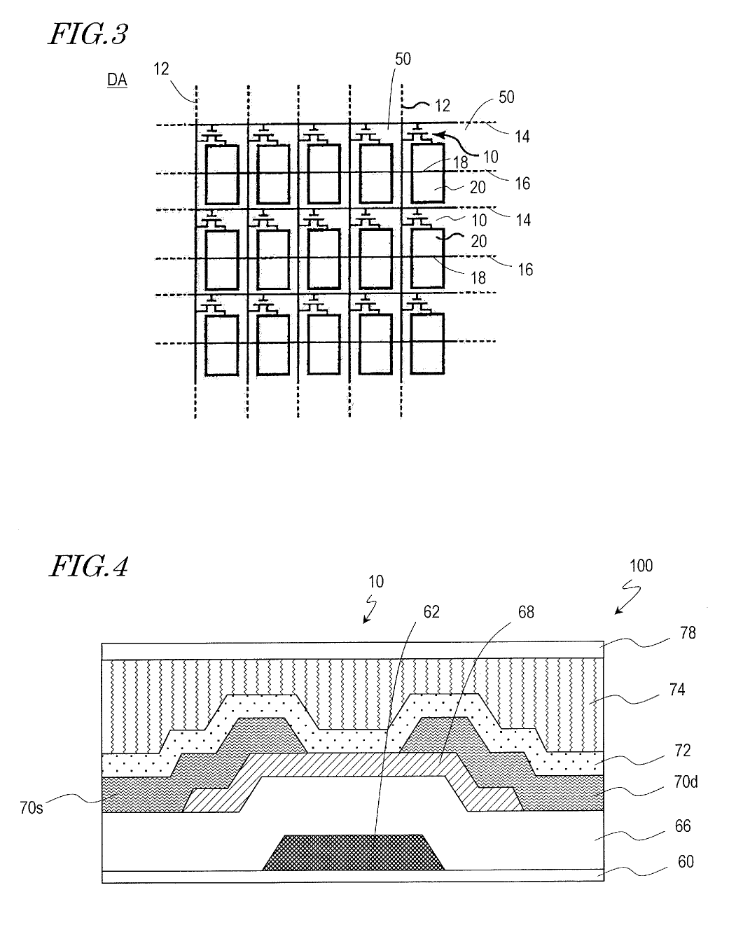

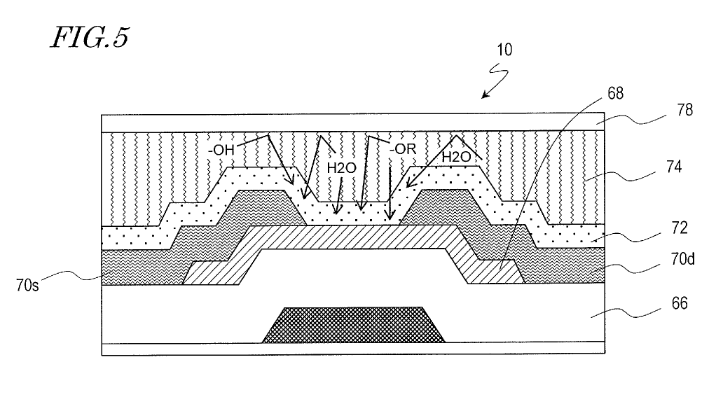

FIG. 4 is a cross-sectional view schematically illustrating the configuration of a TFT 10 on the TFT substrate 100 (which will also be referred to herein as the “semiconductor device 100”) according to this first embodiment.

As shown in FIG. 4, the TFT 10 includes a gate electrode 62 which has been formed on a substrate 60 such as a glass substrate, a gate insulating layer 66 (which will be sometimes simply referred to herein as an “insulating layer” and) which has been formed on the substrate 60 to cover the gate electrode 62, an oxide semiconductor layer 68 which has been stacked on the gate insulating layer 66, a source electrode 70s and a drain electrode 70d which have been formed on the gate insulating layer 66 and the oxide semiconductor layer 68, a protective layer 72 which has been formed on the source and drain electrodes 70s and 70d, an oxygen supplying layer 74 which has been stacked on the protective layer 72, and an anti-diffusion layer 78 which has been stacked on the oxygen supplying layer 74.

As will be described later with reference to FIGS. through 14, a pixel electrode 20 of a transparent conductive material has been formed on the anti-diffusion layer 78. A contact hole has been cut through the anti-diffusion layer 78, the interlayer insulating layer 74 and the protective layer 72 under the pixel electrode 20, and the pixel electrode 20 contacts with the drain electrode 70d of the TFT 10 at the bottom of the contact hole.

The gate electrode 62 may have a double-layer structure in which an upper gate electrode of copper (Cu) has been stacked on a lower gate electrode of titanium (Ti), for example. Alternatively, the gate electrode may also have a triple-layer structure consisting of Ti, Al (aluminum) and Ti layers. The gate insulating layer 66 is made of silicon nitride, for example. Alternatively, the gate insulating layer 66 may be made of silicon dioxide. Or the gate insulating layer 66 may also have a double-layer structure consisting of a silicon nitride layer and a silicon dioxide layer.

The oxide semiconductor layer 68 is made of an In—Ga—Zn—O (IGZO) based semiconductor. The source electrode 70s and the drain electrode 70d which have been formed on the oxide semiconductor layer 68 are obtained by patterning a conductive layer with a triple-layer structure consisting of Ti, Al and Ti layers. Alternatively, the source electrode 70s and the drain electrode 70d may also have a double-layer structure consisting of Al and Ti layers, Cu and Ti layers or Cu and Mo (molybdenum) layers. The protective layer 72 is made of either silicon dioxide (SiO₂) or silicon nitride (SiNₓ). Some configuration may have no protective layers 72. The anti-diffusion layer 78 is made of silicon dioxide (SiO₂), silicon nitride (SiNₓ) or silicon oxynitride (SiNO).

The oxygen supplying layer 74 is made of a material including water (H₂O), an OR group, or an OH group. In this embodiment, the oxygen supplying layer 74 has been formed by spin-coating the substrate with an acrylic resin, for example. The spin on glass (SOG) material may include a silicone resin, silanol (such as Si(OH)₄), alkoxy silane or siloxane resin, etc. Alternatively, the oxygen supplying layer 74 may also be made of any other resin material such as a silanol group or an Si—OH group. Still alternatively, the oxygen supplying layer 74 may also be made of a resin material such as an ester polymer resin or a CO—OR group.

As shown in FIG. 5, since the oxygen supplying layer 74 includes H₂O, an OR group, or an OH group, that H₂O, an OR group, or an OH group diffuses from the oxygen supplying layer 74 toward the channel portion of the oxide semiconductor layer 68 through the protective layer 72 during a heat treatment process such as an annealing process, thus repairing defects that have been caused due to the presence of oxygen deficiencies in the oxide semiconductor layer 68. As a result, a high-quality semiconductor device which has improved TFT performance and of which the characteristic varies much less significantly from one TFT to another can be provided. In addition, since the anti-diffusion layer 78 is arranged on the oxide semiconductor layer 74, H₂O, OR groups, or OH groups which have moved upward from the oxygen supplying layer 74 are reflected from the bottom of the anti-diffusion layer 78 toward the oxide semiconductor layer 68. That is why if the heat treatment process is carried out after the anti-diffusion layer 78 has been formed, more H₂O, OR groups, or OH groups are supplied onto the oxide semiconductor layer 68 and a lot more defects can be repaired.

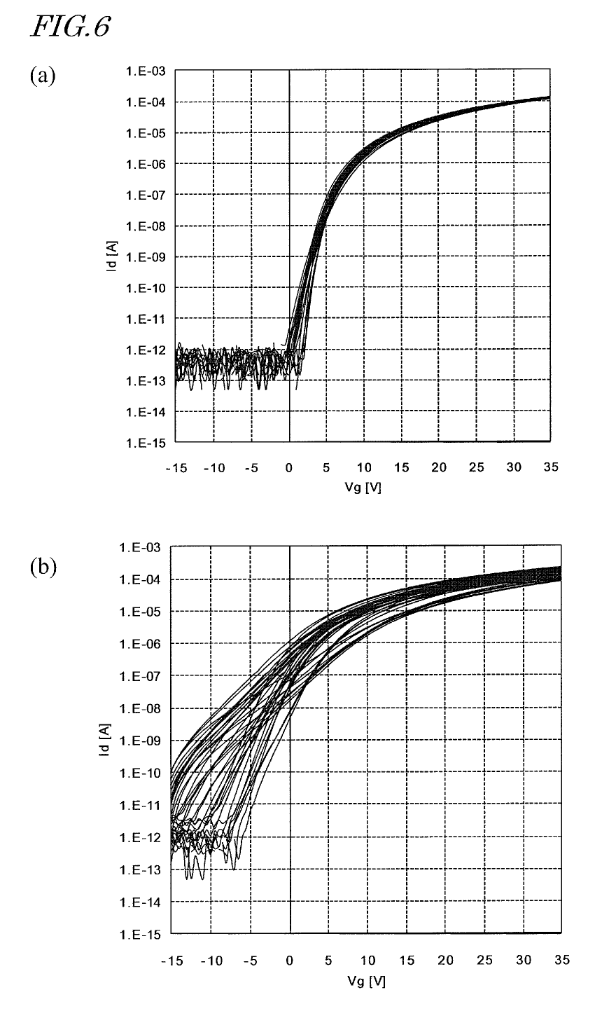

FIG. 6(a) is a graph showing the voltage-current characteristics of multiple TFTs 10, while FIG. 6(b) is a graph showing the voltage-current characteristics of multiple TFTs with no oxygen supplying layer or anti-diffusion layer. In these graphs, the abscissa represents the gate voltage value and the ordinate represents the source-drain current value. As can be seen from FIG. 6(a), in the TFTs 10 of the first embodiment, the amount of current flowing rises steeply at a gate voltage of around 0 V and there is less variation between the characteristics (i.e., S curves) of those TFTs 10. These results reveal that in any of these TFTs 10, an appropriate current value can be obtained according to the voltage applied, no sooner has the TFT 10 been turned ON. On the other hand, in the TFTs having no oxygen supplying layer or anti-diffusion layer, the amount of ON-state current flowing rises much less steeply, and there is a significant variation between their rising points as shown in FIG. 6(b). In addition, there is a significant variation in OFF-state current value, too. Comparing these results, it can be seen that with the TFTs 10 of this first embodiment, a high-performance semiconductor device with further stabilized TFT characteristics can be obtained.

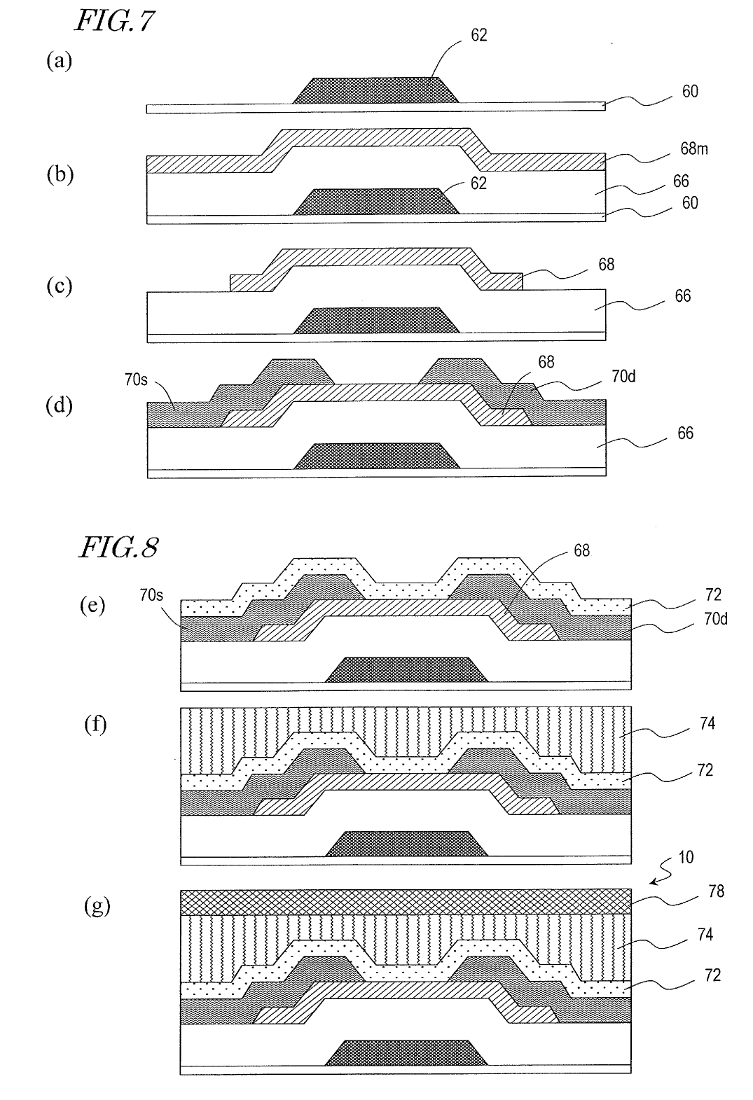

Hereinafter, it will be described with reference to FIGS. 7 and 8 how to fabricate the TFT substrate 100. FIGS. 7(a) through 7(d) and FIGS. 8(e) through 8(g) are schematic cross-sectional views illustrating the respective manufacturing process steps to fabricate the TFT substrate 100.

Step (A):

First of all, Ti and Cu layers are stacked in this order on a substrate 60 by sputtering process, for example. In this case, the Ti layer may be deposited to a thickness of 30 to 150 nm, and the Cu layer may be deposited to a thickness of 200 to 500 nm. Next, these two layers stacked are patterned by known photolithography and wet etching techniques (which will be referred to herein as a “first masking process step”), thereby obtaining the gate electrode 62 shown in FIG. 7(a). Although not shown in FIG. 7(a), scan lines 14, storage capacitor lines 16, storage capacitor electrodes and lower wirings are also formed at the same time. After that, the remaining resist pattern is stripped and the substrate is cleaned.

Step (B):

Next, a gate insulating layer 66 is deposited over the substrate 60 so as to cover the gate electrode 62. The gate insulating layer 66 may be a silicon nitride layer which has been deposited to a thickness of 100 to 700 nm by plasma CVD process. Alternatively, silicon dioxide (SiO₂) may be deposited instead of silicon nitride. Or silicon nitride and silicon dioxide may be both deposited.

Subsequently, as shown in FIG. 7(b), an oxide semiconductor material 68m is stacked on the gate insulating layer 66. The oxide semiconductor material 68m may be In—Ga—Zn—O (IGZO), for example, and may be deposited to a thickness of 10 to 100 nm by sputtering process. Alternatively, the oxide semiconductor material 68m may be deposited by application or ink jet technique. The oxide semiconductor material does not have to be IGZO but may also be any other kind of oxide semiconductor material.

Step (C):

Thereafter, the oxide semiconductor material 68m deposited is patterned by photolithographic process and wet etching process using oxalic acid, for example (which will be referred to herein as a “second masking process”), thereby obtaining an oxide semiconductor layer 68 including the channel layer of the TFT 10 as shown in FIG. 7(c). After that, the remaining resist pattern is stripped and the substrate is cleaned.

Step (D):

Next, Ti, Al and Ti layers are deposited by sputtering process in this order over the gate insulating layer 66 to cover the oxide semiconductor layer 68. Subsequently, these three layers are patterned by photolithographic and wet etching processes, thereby obtaining source and drain electrodes 70s and 70d as shown in FIG. 7(d) (which will be referred to herein as a “third masking process”). After that, the remaining resist pattern is stripped and the substrate is cleaned. Optionally, the wet etching process may be replaced with a dry etching process. Also, instead of stacking Ti, Al and Ti layers, Al and Ti layers, Al and Mo layers, Cu and Ti layers, or Cu and Mo layers may be stacked. Still alternatively, any of these metals could be used as a single layer. In this process step, signal lines 12, storage capacitor counter electrodes, upper wirings and other members (none of which are shown) are also formed at the same time.

Step (E):

Next, as shown in FIG. 8(e), silicon dioxide is deposited by CVD process all over the substrate, thereby forming a protective layer 72. Optionally, silicon nitride may be deposited instead of silicon dioxide, or silicon dioxide and silicon nitride may be stacked one upon the other. The protective layer 72 suitably has a thickness of 25 nm to 350 nm. The reason is as follows. Specifically, if the thickness of the protective layer 72 were less than 25 nm, the layer could not work fine as a protective layer and the reliability of the TFT would decrease. However, if the thickness of the protective layer 72 were greater than 350 nm, then there should be a concern about film peeling due to a film stress. Also, in that case, it would take a lot of time to deposit and etch the protective layer 72, thus resulting in poor productivity.

Step (F):

Subsequently, as shown in FIG. 8(f), the protective layer is coated with an oxygen supplying material 74m of an acrylic resin. Alternatively, the protective layer 72 may also be spin-coated with an SOG material such as a silicone resin. As the oxygen supplying material 74m, a material including silanol (Si(OH)₄), alkoxy silane, or a siloxane resin may be used. Alternatively, the oxygen supplying layer 74 may also be made of any other resin material including a silanol group or an Si—OH group. Still alternatively, the oxygen supplying layer 74 may also be made of a resin material including an ester polymer resin or a CO—OR group. The oxygen supplying layer 74 suitably has a thickness of 500 nm to 3500 nm for the following reasons. Specifically, if the thickness of the oxygen supplying layer 74 were less than 500 nm, the effect of the present invention could not be achieved. However, if the thickness of the oxygen supplying layer 74 were greater than 3500 nm, then there should be a concern about film peeling or a decline in productivity.

Step (G):

Subsequently, silicon dioxide is deposited by CVD process over the entire surface of the substrate, as well as over the oxygen supplying layer 74, thereby forming an anti-diffusion layer 78 as shown in FIG. 8(g). Optionally, silicon nitride may be deposited instead of silicon dioxide, or silicon dioxide and silicon nitride may be stacked one upon the other.

The anti-diffusion layer 78 may have a thickness of 50 nm to 500 nm. Thereafter, an annealing process is carried out at a temperature of 200 to 400° C. in an air atmosphere, thereby completing the TFT 10. If the anti-diffusion layer 78 is implemented as either a silicon nitride film or a stack of silicon dioxide and silicon nitride films and if the protective layer 72 is implemented as a silicon dioxide film, the good anti-diffusion effect and the protective film function can be achieved at the same time by the anti-diffusion layer 78 and the protective layer 72, respectively. It should be noted that the protective layer 72 needs to have not only the function as a protective film but also the property to transmit H₂O, OR groups or OH groups appropriately. A silicon nitride film has the property of transmitting H₂O, OR groups or OH groups less easily than a silicon dioxide film.

During the annealing process, H₂O, OH groups or OR groups diffuse from the oxygen supplying layer 74 toward the channel portion of the oxide semiconductor layer 68 via the protective layer 72, thereby repairing the defects that have been caused due to the presence of oxygen deficiencies in the oxide semiconductor layer 68. Also, H₂O, OR groups, or OH groups which have moved upward from the oxygen supplying layer 74 are reflected from the bottom of the anti-diffusion layer 78 toward the oxide semiconductor layer 68. That is why more H₂O, OR groups, or OH groups are supplied onto the oxide semiconductor layer 68 and a lot more defects can be repaired.

Thereafter, a transparent conductive material is deposited over the anti-diffusion layer 78 by sputtering process, for example. In this process step, the transparent conductive material is also deposited inside a contact hole that has been cut through the protective layer 72, the oxygen supplying layer 74 and the anti-diffusion layer 78 over the drain electrode 70d to contact with the drain electrode 70d at the bottom of the contact hole. ITO may be used as the transparent conductive material. Alternatively, IZO, ZnO or any other appropriate material may also be used as the transparent conductive material. Subsequently, the transparent electrode layer is patterned by known photolithographic process, thereby forming the pixel electrodes 20.

By performing these process steps, a TFT substrate 100 with TFTs 10 is completed.

Next, first, second and third exemplary configurations for the connecting portion 25 of this TFT substrate 100 will be described with reference to FIGS. 9 through 11, which schematically illustrate cross sections of the connecting portion 25 with the first, second and third exemplary configurations, respectively.

First Exemplary Configuration:

As shown in FIG. 9, the connecting portion 25 with the first exemplary configuration includes a lower wiring 62b which has been formed on a substrate 60, a gate insulating layer 66 which has been stacked on the lower wiring 62d, an oxide semiconductor layer 68 which has been stacked on the gate insulating layer 66, and an upper wiring 70u which has been formed on the oxide semiconductor layer 68. In one embodiment, the oxide semiconductor layer 68 may be omitted. The lower wiring 62d is a metal layer which has been formed of the same material and at the same time as the gate electrode 62. The upper wiring 70u is a metal layer which has been formed of the same material and at the same time as the source and drain electrodes 70s and 70d.

In this connecting portion 25, holes have been cut through the oxide semiconductor layer 68 and the gate insulating layer 66 so that these two holes are vertically continuous with each other to define a contact hole 25ha that runs through these two layers. The hole of the gate insulating layer 66 is larger in size than that of the oxide semiconductor layer 68. And in the contact hole 25ha, the gate insulating layer 66 and the oxide semiconductor layer 68 have stepped side surfaces. The upper and lower wirings 70u and 62d are connected together through the contact hole 25ha. In other words, the upper wiring 70u which has been formed in the contact hole 25ha is connected to the lower wiring 62d at the bottom of the contact hole 25ha. In an embodiment in which the connecting portion 25 has no oxide semiconductor layer 68, the contact hole 25ha is arranged to run through only the gate insulating layer 66.

If the contact hole 25ha has too steep a side surface while a metal layer to define the upper wiring 70u is being deposited, then the metal layer would be easily cut off at the side surface to possibly cause disconnection at this connecting portion. In this exemplary configuration, however, the upper wiring 70u is formed on the stepped side surfaces of the gate insulating layer 66 and the oxide semiconductor layer 68, not on such a steep side surface, the upper wiring 70u would not be cut off easily. As a result, a highly reliable connecting portion 25 can be obtained.

Second Exemplary Configuration:

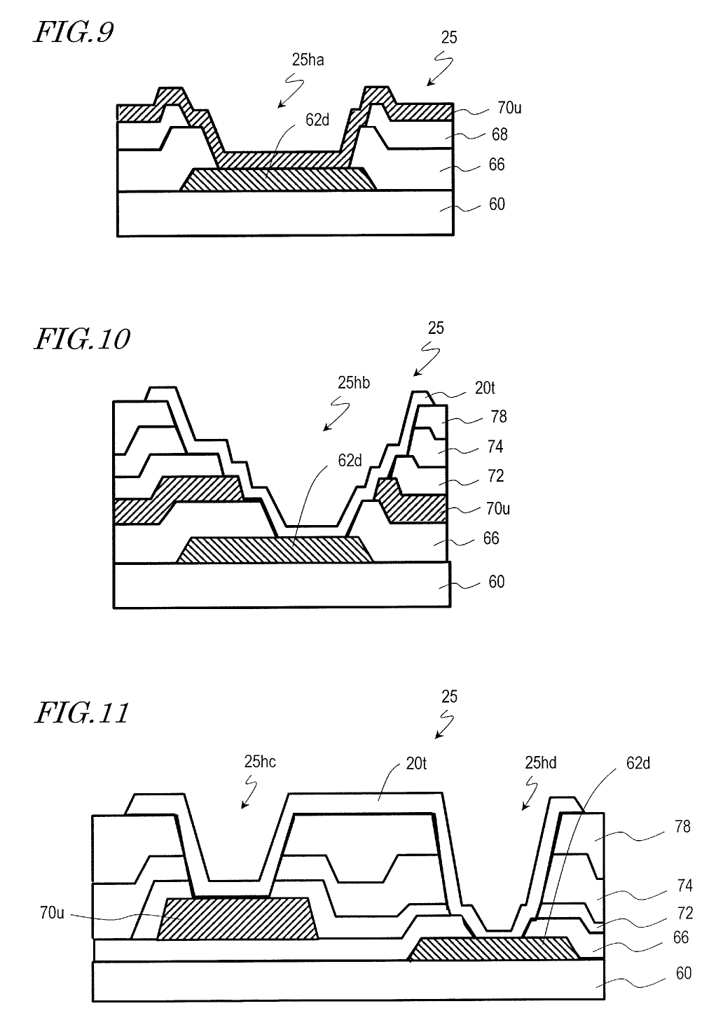

As shown in FIG. 10, the connecting portion 25 with the second exemplary configuration includes a lower wiring 62d which has been formed on a substrate 60, a gate insulating layer 66 which has been stacked on the lower wiring 62d, an upper wiring 70u which has been formed on the gate insulating layer 66, a protective layer 72 which has been stacked on the upper wiring 70u, an oxygen supplying layer 74 which has been stacked on the protective layer 72, an anti-diffusion layer 78 which has been stacked on the oxygen supplying layer 74, and a conductive layer 20t which has been stacked on the anti-diffusion layer 78. The lower wiring 62d is a metal layer which has been formed of the same material and at the same time as the gate electrode 62. The upper wiring 70u is a metal layer which has been formed of the same material and at the same time as the source and drain electrodes 70s and 70d. And the conductive layer 20t has been formed of the same material and at the same time as the pixel electrodes 20.

In this connecting portion 25, holes have been cut through the gate insulating layer 66, the upper wiring 70u, the protective layer 72, the oxygen supplying layer 74, and the anti-diffusion layer 78 so that their holes are vertically continuous with each other and increase their sizes upward (i.e., from the lowermost layer toward the uppermost layer). And a contact hole 25hb is defined to run through these layers. In this contact hole 25hb, the ends of those layers are arranged stepwise so that the higher the level of a layer, the outer its ends are located.

The upper and lower wirings 70u and 62d are connected together through the conductive layer 20t that has been deposited in the contact hole 25hb. That is to say, the conductive layer 20t has been deposited in the contact hole 25hb to cover the respective side surfaces of the gate insulating layer 66, the upper wiring 70u, the protective layer 72, the oxygen supplying layer 74, and the anti-diffusion layer 78. The conductive layer 20t and the upper wiring 70u are connected together at its side surface, and the conductive layer 20t and the lower wiring 62d are connected together at the bottom of the contact hole 25hb.

In forming the conductive layer 20t in the contact hole 25hb, a metal such as ITO or IZO is deposited by sputtering process. However, if the contact hole 25hb had too steep a side surface, the metal layer would be cut off easily and contact between the metal layer and the upper wiring 70u would be often insufficient. Also, if one tried to form those layers so that their ends are perfectly vertically aligned with each other, then the ends of a lower layer could be located outside of those of an upper layer due to a mask misalignment in a photolithographic process, a variation in etching shift or an overhang. In that case, the conductive layer 20t could be disconnected.

In this exemplary configuration, however, the side surfaces of those layers are arranged so that the higher the level of a layer, the outer its ends are located. That is why the contact hole 25hb comes to have a stepped side surface, thus preventing the conductive layer 20t from being disconnected and also preventing the conductive layer 20t and the upper wiring 70u from contacting with each other insufficiently. In addition, since the respective layers that form the multilayer structure are connected together through a single contact hole, the connecting portion can have a reduced area. As a result, the TFT substrate can have a higher density and a smaller size. On top of that, the contact hole 25hb may also be cut by etching all of those layers at a time through half-tone exposure or resist asking process, for example. In that case, the productivity will increase and the TFT substrate can be fabricated at a lower cost as well.

Third Exemplary Configuration:

As shown in FIG. 11, the connecting portion 25 with the third exemplary configuration includes a lower wiring 62d which has been formed on a substrate 60, a gate insulating layer 66 which has been stacked on the lower wiring 62d, an upper wiring 70u which has been formed on the gate insulating layer 66, a protective layer 72 which has been stacked on the upper wiring 70u, an oxygen supplying layer 74 which has been stacked on the protective layer 72, an anti-diffusion layer 78 which has been stacked on the oxygen supplying layer 74, and a conductive layer 20t which has been stacked on the anti-diffusion layer 78. The lower wiring 62d is a metal layer which has been formed of the same material and at the same time as the gate electrode 62. The upper wiring 70u is a metal layer which has been formed of the same material and at the same time as the source and drain electrodes 70s and 70d. And the conductive layer 20t has been formed of the same material and at the same time as the pixel electrodes 20.

In this connecting portion 25, a first contact hole 25hc has been cut to run through the anti-diffusion layer 78, the oxygen supplying layer 74, and the protective layer 72, and a second contact hole 25hd has been cut to run through the anti-diffusion layer 78, the oxygen supplying layer 74, the protective layer 72 and the gate insulating layer 66. The upper wiring 70u and the conductive layer 20t are connected together inside the first contact hole 25hc. That is to say, in the contact hole 25hc, the conductive layer 20t has been deposited to cover the respective side surfaces of the anti-diffusion layer 78, the oxygen supplying layer 74, and the protective layer 72. And the conductive layer 20t and the upper wiring 70u are connected together at the bottom of the contact hole 25hc. On the other hand, the conductive layer 20t and the lower wiring 62d are connected together inside the second contact hole 25hd. That is to say, in the contact hole 25hd, the conductive layer 20t has been deposited to cover the respective side surfaces of the anti-diffusion layer 78, the oxygen supplying layer 74, the protective layer 72 and the gate insulating layer 66. And the conductive layer 20t and the lower wiring 62d are connected together at the bottom of the contact hole 25hd.

In this manner, the upper and lower wirings 70u and 62d are electrically connected together via the conductive layer 20t. As in the first and second exemplary configurations, the contact holes 25hc and 25hd may each have a stepped side surface. Then, it is possible to prevent the conductive layer 20t from getting disconnected.

Hereinafter, other embodiments of the present invention will be described as second through fourteenth embodiments. In the following description, any component having substantially the same function as its counterpart of the first embodiment will be identified by the same reference numeral, and detailed description thereof will be omitted herein. The same effect can be achieved by such a component with a similar configuration to what has already been described. Any of the TFTs and TFT substrates to be described below for those other embodiments are basically replaceable with the TFT 10 and TFT substrate 100 of the first embodiment described above.

### Embodiment 2

FIG. 12 is a cross-sectional view schematically illustrating the configuration of a TFT substrate 100 as a second embodiment. The TFT substrate 100 of this embodiment has basically the same configuration as the TFT substrate 100 of the first embodiment except for the following respects. The TFT substrate 100 of this embodiment may be used as the TFT substrate 100 of the liquid crystal display device 1000 shown in FIGS. 1 and 2.

As shown in FIG. 12, the TFT substrate 100 includes a connecting portion 25, a TFT 10, and a storage capacitor (Cs) 18. The connecting portion 25 of this second embodiment has basically the same configuration as the connecting portion with the second exemplary configuration of the first embodiment. In this second embodiment, however, an oxide semiconductor layer 68 is arranged between the gate insulating layer 66 and the upper wiring 70u of the second exemplary configuration, and a contact hole 25hb has been cut to run through the gate insulating layer 66, the oxide semiconductor layer 68, the upper wiring 70u, the protective layer 72, the oxygen supplying layer 74 and the anti-diffusion layer 78.

In the connecting portion 25 of this embodiment, the respective layers are arranged on the side surface of the contact hole 25hb so that the higher the level of a layer, the outer its ends are located. That is why the contact hole 25hb comes to have a stepped side surface, thus preventing the conductive layer 20t from being disconnected and also preventing the conductive layer 20t and the upper wiring 70u from contacting with each other insufficiently. In addition, since the respective wirings are connected together through a single contact hole, the connecting portion can have a reduced area. Optionally, the connecting portion 25 may have the first or third exemplary configuration of the first embodiment described above.

In the region where the storage capacitor 18 has been formed (which will be referred to herein as a “Cs region”), a storage capacitor electrode 62c, a gate insulating layer 66, a protective layer 72, an oxygen supplying layer 74, an anti-diffusion layer 78 and a storage capacitor counter electrode 20c have been stacked one upon the other in this order on the substrate 60. The storage capacitor electrode 62c is made of the same material, and has been formed in the same process step, as the gate electrode of the TFT 10. And the storage capacitor counter electrode 20c is made of the same material, and has been formed in the same process step, as the pixel electrode 20.

Over the storage capacitor electrode 62c, a hole has been cut through the gate insulating layer 66, the protective layer 72 and the oxygen supplying layer 74. And the anti-diffusion layer 78 and the storage capacitor counter electrode 20c have been stacked in that hole, in which the anti-diffusion layer 78 contacts with the storage capacitor electrode 62c and the storage capacitor counter electrode 20c contacts with the anti-diffusion layer 78. A storage capacitor is formed by the storage capacitor electrode 62c, the storage capacitor counter electrode 20c that faces the storage capacitor electrode 62c, and the anti-diffusion layer 78 interposed between those two electrodes. By adopting this configuration, the gap between the two electrodes can be narrower. That is why even in a TFT substrate 100 with a multilayer structure including the oxygen supplying layer 74, a storage capacitor 18 with large capacitance can be formed in a narrow area.

Next, a first modified example of the TFT substrate 100 according to this second embodiment will be described with reference to FIG. 13. The TFT substrate 100 of this first modified example has basically the same configuration as the TFT substrate 100 of the second embodiment except for the following respects. Thus, the following description will be focused on their differences.

As shown in FIG. 13, the TFT substrate 100 includes a connecting portion 25, a TFT 10 and a storage capacitor (Cs) 18. In the Cs region where the storage capacitor 18 has been formed, a storage capacitor electrode 62c, a gate insulating layer 66, a protective layer 72, an oxygen supplying layer 74, a conductive layer 22 made of a transparent electrode material (which will be referred to herein as a “first conductive layer”), an anti-diffusion layer 78 and a storage capacitor counter electrode 20c (which will be referred to herein as a “second conductive layer”) have been stacked one upon the other in this order on the substrate 60.

Over the storage capacitor electrode 62c, a hole has been cut through the gate insulating layer 66, the protective layer 72 and the oxygen supplying layer 74. And the conductive layer 22, the anti-diffusion layer 78 and the storage capacitor counter electrode 20c have been stacked in that hole, in which the conductive layer 22 contacts with the storage capacitor electrode 62c and the anti-diffusion layer is interposed between the conductive layer 22 and the storage capacitor counter electrode 20c.

A storage capacitor 18 is formed by the storage capacitor electrode 62c and the conductive layer 22, the storage capacitor counter electrode 20c that faces the storage capacitor electrode 62c and the conductive layer 22, and the anti-diffusion layer 78. By adopting this configuration, the gap between the two electrodes can be narrower. That is why even in a TFT substrate 100 with a multilayer structure including the oxygen supplying layer 74, a storage capacitor 18 with large capacitance can be formed in a narrow area.

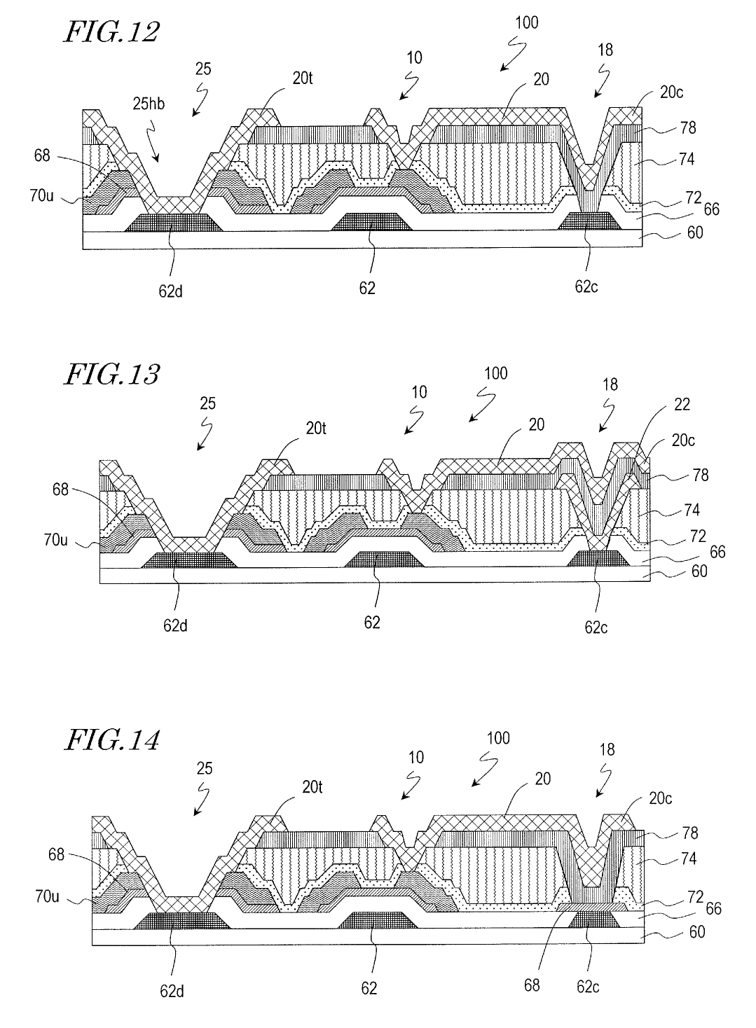

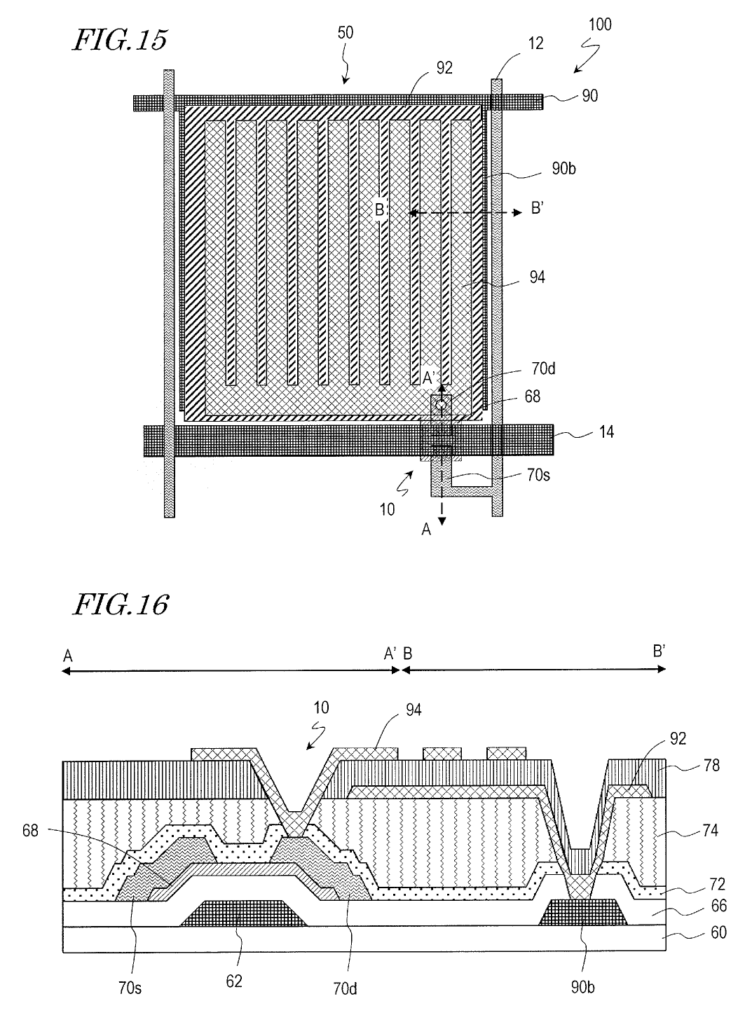

Next, a second modified example of the TFT substrate 100 according to this second embodiment will be described with reference to FIG. 14. The TFT substrate 100 of this second modified example has basically the same configuration as the TFT substrate 100 of the second embodiment except for the following respects. Thus, the following description will be focused on their differences.

As shown in FIG. 14, the TFT substrate 100 includes a connecting portion 25, a TFT 10 and a storage capacitor (Cs) 18. In the Cs region where the storage capacitor 18 has been formed, a storage capacitor electrode 62c, a gate insulating layer 66, an oxide semiconductor layer 68, a protective layer 72, an oxygen supplying layer 74, an anti-diffusion layer 78 and a storage capacitor counter electrode 20c have been stacked one upon the other in this order on the substrate 60.

The upper surface of the storage capacitor electrode 62c is not covered with the gate insulating layer 66 but contacts with the oxide semiconductor layer 68. Over the oxide semiconductor layer 68, a hole has been cut through the protective layer 72 and the oxygen supplying layer 74 and the anti-diffusion layer 78 and the storage capacitor counter electrode 20c are stacked in that hole, in which the oxide semiconductor layer 68 contacts with the anti-diffusion layer 78 and the anti-diffusion layer 78 contacts with the storage capacitor counter electrode 20c.

A storage capacitor 18 is formed by the storage capacitor electrode 62c and the oxide semiconductor layer 68, the storage capacitor counter electrode 20c that faces the storage capacitor electrode 62c and the oxide semiconductor layer 68, and the anti-diffusion layer 78. The oxide semiconductor layer 68 has turned into a conductor by going through a heat treatment, and therefore, functions as a storage capacitor electrode. Thus, the gap between the two electrodes can be narrower. As a result, even in a TFT substrate 100 with a multilayer structure including the oxygen supplying layer 74, a storage capacitor 18 with large capacitance can be formed in a narrow area. In addition, the patterning and heat treatment process steps on the oxide semiconductor layer 68 in the Cs section are carried out simultaneously with the patterning and heat treatment process steps on the oxide semiconductor layer 68 of the TFT 10. Consequently, a high-performance storage capacitor 18 can be formed efficiently without increasing the number of process steps.

### Embodiment 3

Hereinafter, a display device as a third embodiment of the present invention will be described. A display device according to the third embodiment is a fringe field (FFS) type liquid crystal display device. In the following description, any component having substantially the same function as its counterpart of the first embodiment will be identified by the same reference numeral. And the following description will be focused on their differences.

FIG. 15 is a plan view schematically illustrating a configuration for a pixel 50 of a TFT substrate 100 according to the third embodiment. FIG. 16 is a schematic cross-sectional view of the TFT substrate 100 according to the third embodiment as viewed on the plane A-A′ (a cross section of the TFT 10) and the plane B-B′.

As shown in FIGS. 15 and 16, each pixel 50 of the TFT substrate 100 includes a TFT 10, an upper electrode (pixel electrode) 94 connected to the drain electrode 70d of the TFT 10, and a lower electrode 92. The TFT 10 has the same configuration as the TFT 10 of the first and second embodiments described above. On the TFT substrate 100, a common line 90 is arranged to run parallel to the scan line 14. A region surrounded with the scan line 14, the common line 90, and two adjacent signal lines 12 corresponds to one pixel 50.

A branch line 90b is extended from the common line 90 so as to run parallel to the signal lines 12 around the pixel 50. A contact hole has been cut through the gate insulating layer 66, the protective layer 72 and the oxygen supplying layer 74 on the branch line 90b. And the side surface and bottom of the contact hole are covered with a portion of the lower electrode 92. That is to say, the lower electrode 92 and the branch line 90b (and the common line 90) are connected together through the contact hole. The common line 90 and the branch line 90b are made of the same material, and formed in the same process step, as the gate electrode 62 of the TFT 10.

The upper electrode 94 has a comb tooth shape. The lower electrode 92 is arranged between the oxygen supplying layer 74 and the anti-diffusion layer 78 to cover almost the entire pixel 50. On the other hand, the upper electrode 92 is arranged on the anti-diffusion layer 78. Under the electric field generated between the comb tooth portions (i.e., a plurality of linear portions that run parallel to each other) of the upper electrode 92 and the lower electrode 92, liquid crystal molecules on the upper electrode 94 are aligned to conduct a display operation.

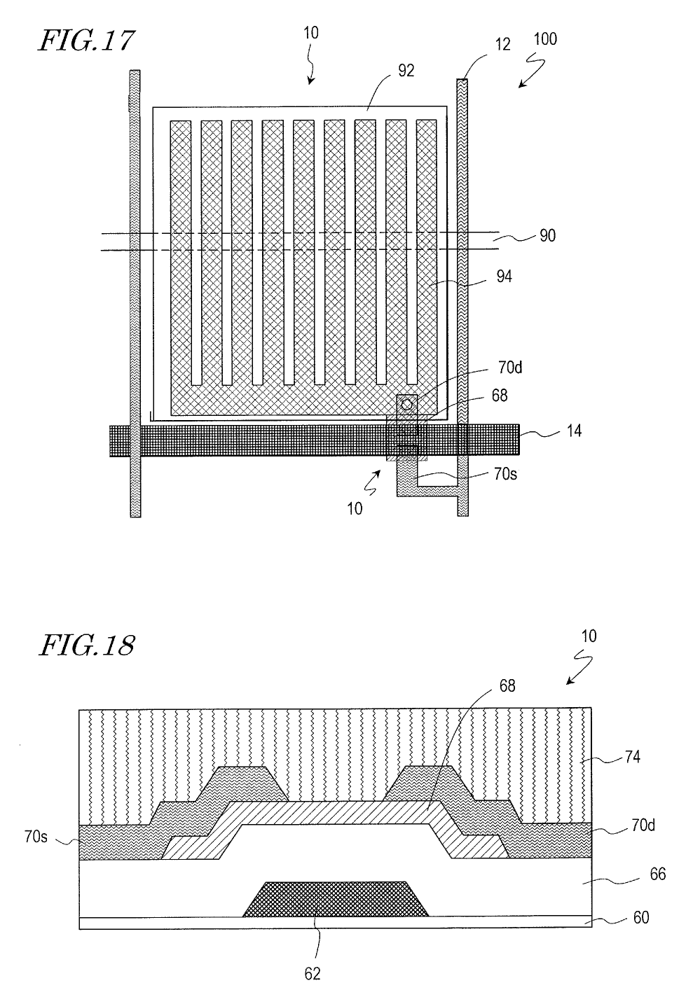

FIG. 17 is a plan view schematically illustrating a modified configuration for each pixel 50 of the TFT substrate 100 according to the third embodiment. As shown in FIG. 17, in this modified example, the common line 90 runs through around the middle of the pixel 10 parallel to the scan line 14, no branch line 90b has been formed, and the common line 90 and the lower electrode 92 are connected together through a contact hole that has been cut over the common line 90.

### Embodiment 4

Hereinafter, a configuration for a TFT 10 as a fourth embodiment of the present invention will be described with reference to FIG. 18, which schematically illustrates a cross section of the TFT 10 according to this fourth embodiment.

The TFT 10 of this fourth embodiment includes a gate electrode 62 which has been formed on a substrate 60, a gate insulating layer 66 which has been stacked on the gate electrode 62, an oxide semiconductor layer 68 which has been stacked on the gate insulating layer 66, a source electrode 70s and a drain electrode 70d which are arranged on the oxide semiconductor layer 68, and an oxygen supplying layer 74 which has been stacked on the oxide semiconductor layer 68 and the source and drain electrodes 70s and 70d to contact with a channel portion of the oxide semiconductor layer 68. This TFT includes every component of the TFT 10 of the first embodiment but the protective layer 72 and the anti-diffusion layer 78 and has the same configuration as the first embodiment other than that.

According to the configuration of this fourth embodiment, the oxygen supplying layer 74 contacts directly with the channel portion of the oxide semiconductor layer 68, and therefore, defects in the channel portion can be repaired efficiently. Nevertheless, effects by the anti-diffusion layer 78 cannot be obtained.

### Embodiment 5

Hereinafter, a configuration for a TFT 10 as a fifth embodiment of the present invention will be described with reference to FIG. 19, which schematically illustrates a cross section of the TFT 10 according to this fifth embodiment.

The TFT 10 of this fifth embodiment includes a gate electrode 62 which has been formed on a substrate 60, a gate insulating layer 66 which has been stacked on the gate electrode 62, an oxide semiconductor layer 68 which has been stacked on the gate insulating layer 66, a source electrode 70s and a drain electrode 70d which are arranged on the oxide semiconductor layer 68, a protective layer 72 which has been stacked on the source and drain electrodes 70s and 70d, and an oxygen supplying layer 74 which has been stacked on the protective layer 72. This TFT 10 includes every component of the TFT 10 of the first embodiment but the anti-diffusion layer 78, and a contact hole 72h has been cut through the protective layer 72. Other than that, the TFT 10 of this embodiment has the same configuration as the first embodiment.

The contact hole 72h is filled with the oxygen supplying layer 74, which contacts with the oxide semiconductor layer 68 at the bottom of the contact hole 72h. Since the oxygen supplying layer 74 and the oxide semiconductor layer 68 contact with each other in the vicinity of the channel, more H₂O can be supplied to the oxide semiconductor layer 68 than in the first embodiment. Also, if the oxygen supplying layer 74 directly contacted with the channel portion of the oxide semiconductor layer 68 as in the fourth embodiment, a lot of impurities could enter the upper surface and its surrounding region of the channel portion and other inconveniences could be caused. According to this embodiment, however, the protective layer 72 is arranged over the channel portion, and therefore, such inconveniences can be avoided and the reliability of the TFT can be increased. Nevertheless, effects by the anti-diffusion layer 78 cannot be obtained.

### Embodiment 6

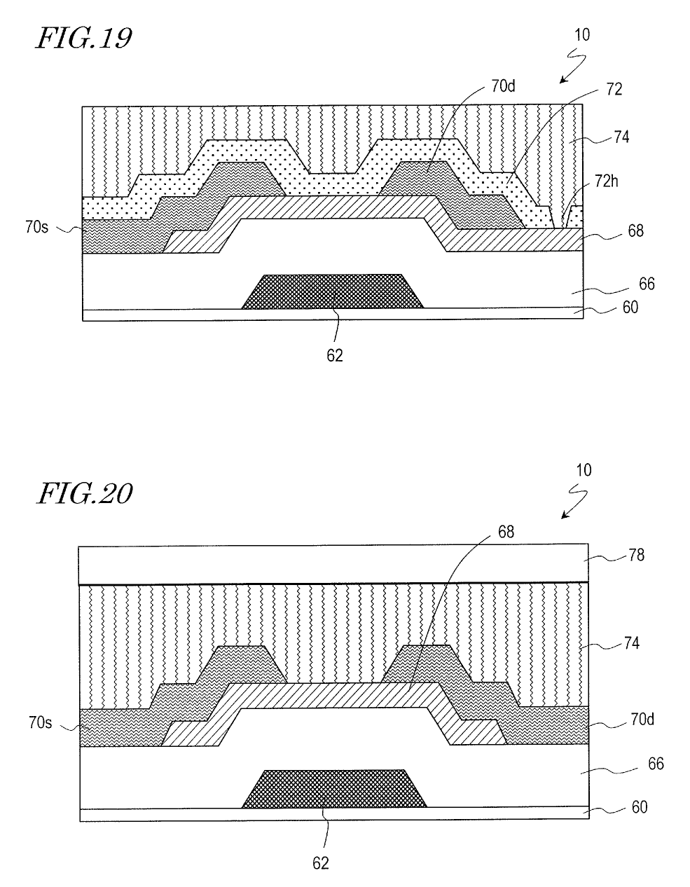

Hereinafter, a configuration for a TFT 10 as a sixth embodiment of the present invention will be described with reference to FIG. 20, which schematically illustrates a cross section of the TFT 10 according to the fifth embodiment.

The TFT 10 of this fifth embodiment includes a gate electrode 62 which has been formed on a substrate 60, a gate insulating layer 66 which has been stacked on the gate electrode 62, an oxide semiconductor layer 68 which has been stacked on the gate insulating layer 66, a source electrode 70s and a drain electrode 70d which are arranged on the oxide semiconductor layer 68, an oxygen supplying layer 74 which has been stacked on the source and drain electrodes 70s and 70d, and an anti-diffusion layer 78 which has been stacked on the oxygen supplying layer 74. This TFT 10 includes every component of the TFT 10 of the first embodiment but the protective layer 72 and includes everything of the fourth embodiment plus the anti-diffusion layer 78.

According to the configuration of this sixth embodiment, the oxygen supplying layer 74 contacts directly with the channel portion of the oxide semiconductor layer 68, and therefore, defects in the channel portion can be repaired efficiently. In addition, effects by the anti-diffusion layer 78 can also be obtained.

### Embodiment 7

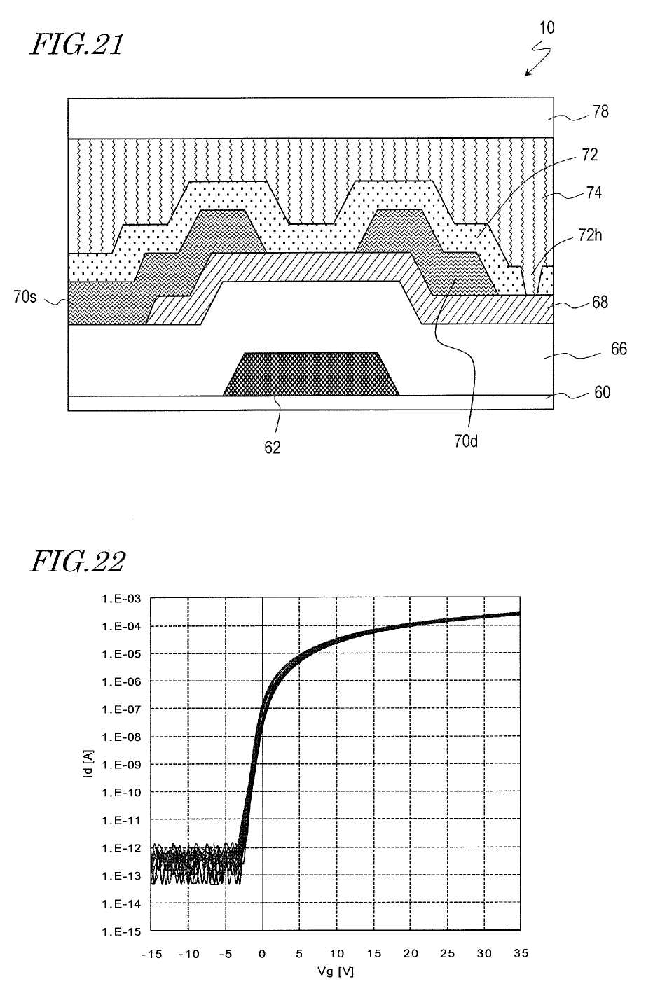

Hereinafter, a configuration for a TFT 10 as a seventh embodiment of the present invention will be described with reference to FIG. 21, which schematically illustrates a cross section of the TFT 10 according to the seventh embodiment.

The TFT 10 of this seventh embodiment includes a gate electrode 62 which has been formed on a substrate 60, a gate insulating layer 66 which has been stacked on the gate electrode 62, an oxide semiconductor layer 68 which has been stacked on the gate insulating layer 66, a source electrode 70s and a drain electrode 70d which are arranged on the oxide semiconductor layer 68, a protective layer 72 which has been stacked on the source and drain electrodes 70s and 70d, an oxygen supplying layer 74 which has been stacked on the protective layer 72, and an anti-diffusion layer 78 which has been stacked on the oxygen supplying layer. This TFT 10 has the same configuration as the TFT 10 of the first embodiment except that a contact hole 72h has been cut through its protective layer 72. Also, this TFT 10 includes everything of the fifth embodiment plus the anti-diffusion layer 78.

The contact hole 72h is filled with the oxygen supplying layer 74, which contacts with the oxide semiconductor layer 68 at the bottom of the contact hole 72h. Since the oxygen supplying layer 74 and the oxide semiconductor layer 68 contact with each other in the vicinity of the channel portion, more H₂O and other groups can be supplied to the oxide semiconductor layer 68 than in the first embodiment. Also, if the oxygen supplying layer 74 directly contacted with the channel portion of the oxide semiconductor layer 68 as in the fourth embodiment, a lot of impurities could enter the upper surface and its surrounding region of the channel portion and other inconveniences could be caused. According to this embodiment, however, the protective layer 72 is arranged over the channel portion, and therefore, such inconveniences can be avoided and the reliability of the TFT can be increased. In addition, according to this embodiment, effects by the anti-diffusion layer 78 can also be obtained.

FIG. 22 is a graph showing the voltage-current characteristics of multiple TFTs 10 according to this embodiment. In FIG. 22, the abscissa represents the gate voltage value and the ordinate represents the source-drain current value. FIG. 6(a) shows the characteristic of the first embodiment in which the protective layer 72 has no contact hole 72h and the oxide semiconductor layer 68 does not directly contact with the oxygen supplying layer 74. Comparing FIG. 22 to FIG. 6(a), it can be seen that in the TFT 10 of the seventh embodiment, the amount of current flowing rises more steeply at a gate voltage of around 0 V, and there is less variation between the characteristics (i.e., S curves) of those TFTs 10, than in the TFT 10 of the first embodiment. These results reveal that in any of these TFTs 10, a more appropriate current value can be obtained with less variation in the seventh embodiment according to the voltage applied, no sooner have the TFTs 10 been turned ON. Comparing these results, it can be seen that by making the oxide semiconductor layer 68 and the oxygen supplying layer 74 directly contact with each other, a high-performance semiconductor device with further stabilized TFT characteristics can be obtained.

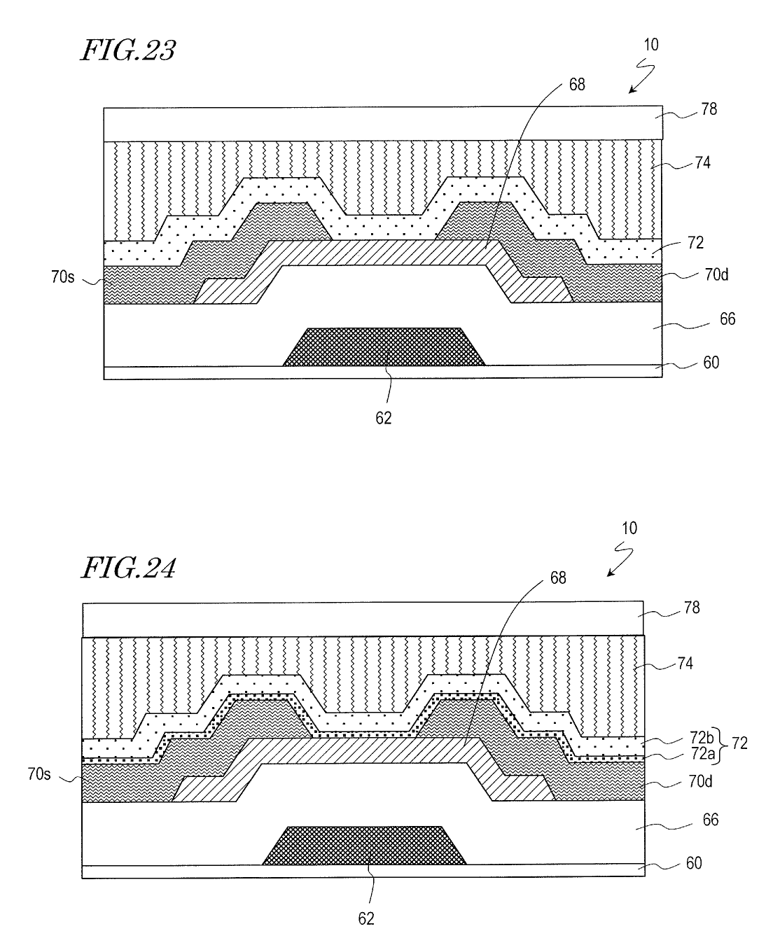

Hereinafter, eighth through thirteenth embodiments of the present invention will be described with reference to FIGS. 23 through 28. In those embodiments to be described below, an anti-diffusion layer 78 is supposed to be arranged on the oxygen supplying layer 74 in each TFT 10. However, the anti-diffusion layer 78 could be omitted in some embodiment.

### Embodiment 8

First, a configuration for a TFT 10 as an eighth embodiment of the present invention will be described with reference to FIG. 23, which schematically illustrates a cross section of the TFT 10 according to the eighth embodiment.

The TFT 10 of this eighth embodiment includes a gate electrode 62 which has been formed on a substrate 60, a gate insulating layer 66 which has been stacked on the gate electrode 62, an oxide semiconductor layer 68 which has been stacked on the gate insulating layer 66, a source electrode 70s and a drain electrode 70d which are arranged on the oxide semiconductor layer 68, a protective layer 72 which has been stacked on the source and drain electrodes 70s and 70d, an oxygen supplying layer 74 which has been stacked on the protective layer 72, and an anti-diffusion layer 78 which has been stacked on the oxygen supplying layer 74.

This TFT 10 has the same configuration as the TFT 10 of the first embodiment. However, the protective layer 72 of this embodiment has a lower density than the protective layer 72 of the first embodiment. The density of the protective layer 72 may be 2.2 g/cm³ in the first embodiment and 2.0 g/cm³ in this eighth embodiment, for example. The protective layer 72 of this eighth embodiment suitably has a density of 1.9 to 2.2 g/cm³. By setting its density to be lower than the protective layer 72 of the first embodiment, the transmittance of H₂O and other groups can be increased and more defects can be repaired in the channel portion.

### Embodiment 9

Next, a configuration for a TFT 10 as a ninth embodiment of the present invention will be described with reference to FIG. 24, which schematically illustrates a cross section of the TFT 10 according to the ninth embodiment.

The TFT 10 of this ninth embodiment includes a gate electrode 62 which has been formed on a substrate 60, a gate insulating layer 66 which has been stacked on the gate electrode 62, an oxide semiconductor layer 68 which has been stacked on the gate insulating layer 66, a source electrode 70s and a drain electrode 70d which are arranged on the oxide semiconductor layer 68, a first protective layer 72a which has been stacked on the source and drain electrodes 70s and 70d, a second protective layer 72b which has been stacked on the first protective layer 72a, an oxygen supplying layer 74 which has been stacked on the second protective layer 72b, and an anti-diffusion layer 78 which has been stacked on the oxygen supplying layer 74.

This TFT 10 has the same configuration as the TFT 10 of the first embodiment except that the protective layer 72 has a double layer structure comprised of the first and second protective layers 72a and 72b. The first protective layer 72a has a higher density than the second protective layer 72b.

The first protective layer 72a may have a density of 2.2 g/cm³ and the second protective layer 72b may have a density of 2.0 g/cm³, for example. The density of the first protective layer 72a suitably falls within the range of 2.1 to 2.4 g/cm³, and the density of the second protective layer 72b suitably falls within the range of 1.9 to 2.2 g/cm³.

If the first protective layer 72a that contacts with the oxide semiconductor layer 68 had a low density, then its reliability as a protective layer would decrease. Thus, in this embodiment, by making a particularly important portion of the protective layer 72 around the interface with the oxide semiconductor layer 68 (e.g., a portion with a thickness of 5 to 25 nm as measured from the interface with the oxide semiconductor layer 68) a high-density film and making the second protective layer 72b a low-density film, the protective layer 72 is given both the function as a protective film and the property of transmitting H₂O, OR groups or OH groups adequately.

### Embodiment 10

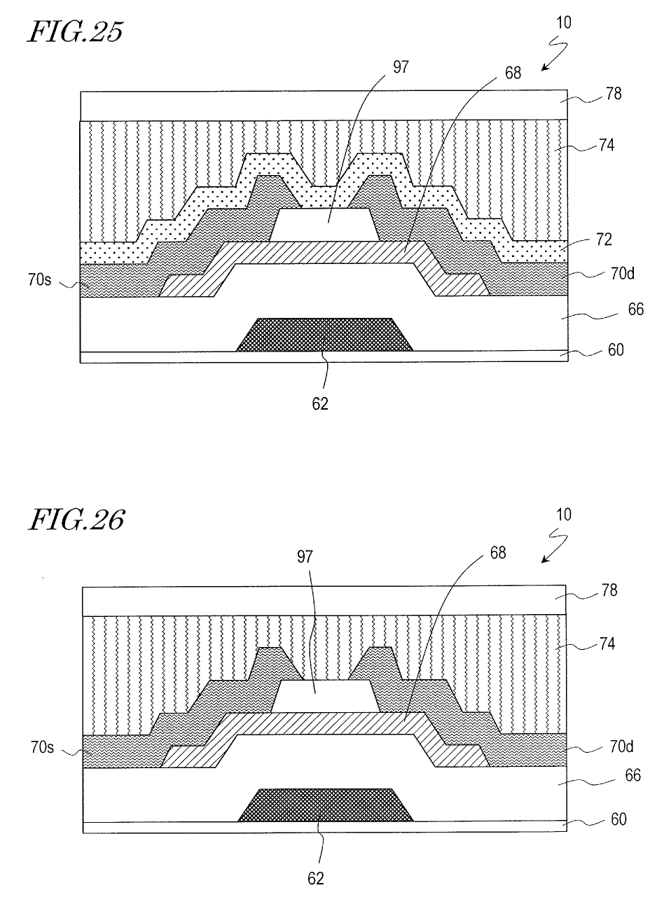

Next, a configuration for a TFT 10 as a tenth embodiment of the present invention will be described with reference to FIG. 25, which schematically illustrates a cross section of the TFT 10 according to the tenth embodiment.

The TFT 10 of this tenth embodiment includes a gate electrode 62 which has been formed on a substrate 60, a gate insulating layer 66 which has been stacked on the gate electrode 62, an oxide semiconductor layer 68 which has been stacked on the gate insulating layer 66, an etch stopper layer (which will be referred to herein as an “ES layer”) 97, a source electrode 70s and a drain electrode 70d which are arranged on the oxide semiconductor layer 68, a protective layer 72 which has been stacked on the ES layer 97 and the source and drain electrodes 70s and 70d, an oxygen supplying layer 74 which has been stacked on the protective layer 72, and an anti-diffusion layer 78 which has been stacked on the oxygen supplying layer 74.

The ES layer 97 is arranged over the channel portion of the oxide semiconductor layer 68 and between the respective ends of the source and drain electrodes 70s and 70d. That is to say, both ends of the ES layer 97 are overlapped by the ends of the source and drain electrodes 70s and 70d, and the upper surface of the central portion of the ES layer 97 contacts with the protective layer 72. The ES layer 97 is either a silicon dioxide film or a stack of a silicon dioxide film and a silicon nitride film (which are stacked in this order so that the silicon nitride film is the upper layer). In this embodiment, the thickness of the silicon dioxide film is set to be 100 nm. By arranging the ES layer 97, the channel portion of the oxide semiconductor layer 68 can be protected from the etch damage to be done while a metal layer to be the source and drain electrodes 70s and 70d is being etched. Consequently, a highly reliable TFT with a further stabilized characteristic can be obtained.

### Embodiment 11

Next, a configuration for a TFT 10 as an eleventh embodiment of the present invention will be described with reference to FIG. 26, which schematically illustrates a cross section of the TFT 10 according to the eleventh embodiment.

The TFT 10 of this eleventh embodiment includes a gate electrode 62 which has been formed on a substrate 60, a gate insulating layer 66 which has been stacked on the gate electrode 62, an oxide semiconductor layer 68 which has been stacked on the gate insulating layer 66, an ES layer 97, a source electrode 70s and a drain electrode 70d which are arranged on the oxide semiconductor layer 68, an oxygen supplying layer 74 which has been stacked on the ES layer 97 and the source and drain electrodes 70s and 70d, and an anti-diffusion layer 78 which has been stacked on the oxygen supplying layer 74.

This embodiment has the same configuration as the tenth embodiment except that this TFT includes no protective layer 72. The oxygen supplying layer 74 makes indirect contact with the channel portion of the oxide semiconductor layer 68 with only the ES layer 97 interposed between them. Thus, H₂O and other groups can move into the channel portion more easily, and defects in the channel portion can be repaired efficiently.

Even though two embodiments in which the TFT 10 has the ES layer 97 have been described as tenth and eleventh embodiments, these are only examples of the present invention and embodiments in which the ES layer 97 is arranged on the channel layer of any of the first through ninth embodiments described above also fall within the scope of the present invention.

### Embodiment 12

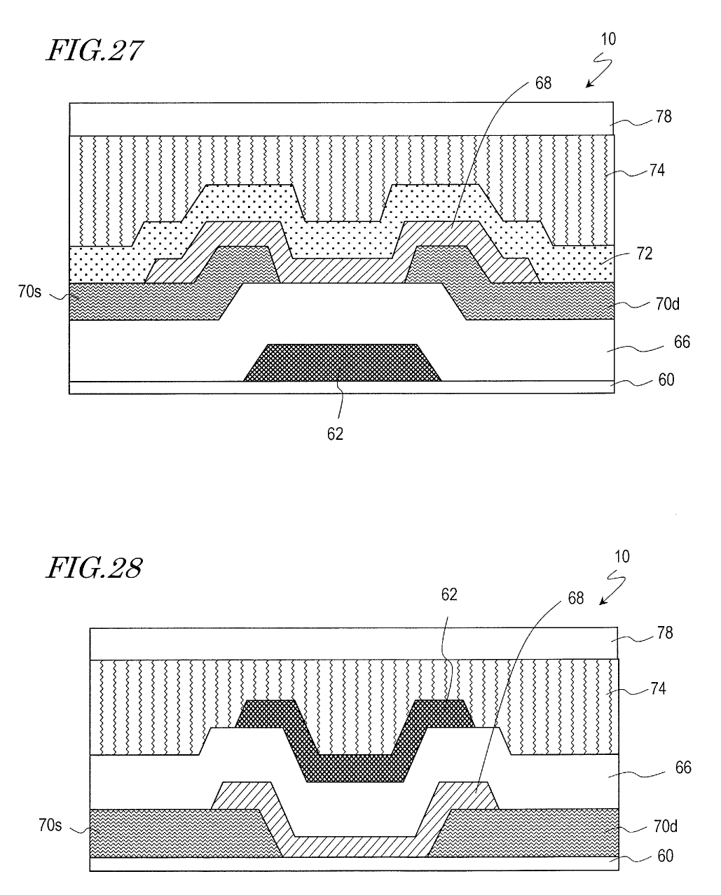

Next, a configuration for a TFT 10 as a twelfth embodiment of the present invention will be described with reference to FIG. 27, which schematically illustrates a cross section of the TFT 10 according to the twelfth embodiment.

The TFT 10 of this twelfth embodiment includes a gate electrode 62 which has been formed on a substrate 60, a gate insulating layer 66 which has been stacked on the gate electrode 62, a source electrode 70s and a drain electrode 70d which are arranged on the gate insulating layer 66, an oxide semiconductor layer 68 which has been stacked on the source and drain electrodes 70s and 70d, a protective layer 72 which has been stacked on the oxide semiconductor layer 68, an oxygen supplying layer 74 which has been stacked on the protective layer 72, and an anti-diffusion layer 78 which has been stacked on the oxygen supplying layer 74.

In this embodiment, the source and drain electrodes 70s and 70d are arranged between the gate insulating layer 66 and the oxide semiconductor layer 68. However, the channel portion of the oxide semiconductor layer 68 which is interposed between the respective ends of the source and drain electrodes 70s and 70d is arranged so that its lower surface directly contacts with the upper surface of the gate insulating layer 66.

According to such a configuration, the oxide semiconductor layer 68 makes indirect contact with the oxygen supplying layer 74 with only the protective layer 72 interposed between them, and neither the source electrode 70s nor the drain electrode 70d is sandwiched between them. Consequently, H₂O and other groups can move into the oxide semiconductor layer 68 more easily, and more defects can be repaired in the oxide semiconductor layer 68.

### Embodiment 13

Next, a configuration for a TFT 10 as a thirteenth embodiment of the present invention will be described with reference to FIG. 28, which schematically illustrates a cross section of the TFT 10 according to the thirteenth embodiment.

The TFT 10 of this thirteenth embodiment is a top gate type TFT and includes a source electrode 70s and a drain electrode 70d which have been formed on a substrate 60, an oxide semiconductor layer 68 which has been stacked on the source and drain electrodes 70s and 70d, a gate insulating layer 66 which has been stacked on the oxide semiconductor layer 68, a gate electrode 62 which has been formed on the gate insulating layer 66, an oxygen supplying layer 74 which has been stacked on the gate electrode 62, and an anti-diffusion layer 78 which has been stacked on the oxygen supplying layer 74.

The channel portion of the oxide semiconductor layer 68 which is interposed between the respective ends of the source and drain electrodes 70s and 70d is arranged in contact with the substrate 60, and the rest is arranged to overlap with the source electrode 70s or the drain electrode 70d. The gate electrode 62 is arranged over the central portion of the oxide semiconductor layer 68, and the gate insulating layer 66 directly contacts with the oxygen supplying layer 74 where the gate electrode 62 is not present.

According to this configuration, H₂O and other groups can move from the oxygen supplying layer 74 into the oxide semiconductor layer 68 via the gate insulating layer 66, and therefore, defects in the oxide semiconductor layer 68 can be repaired. In addition, since the source and drain electrodes 70s and 70d function as an anti-diffusion layer, the defects can be repaired even more effectively.

### Embodiment 14

Hereinafter, an organic EL display device 1002 will be described as a fourteenth embodiment of the present invention.

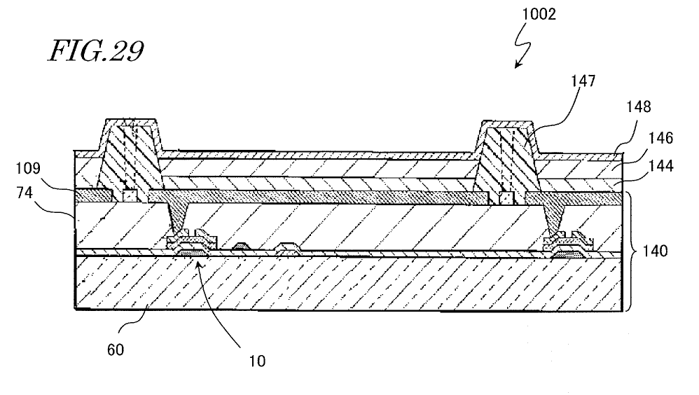

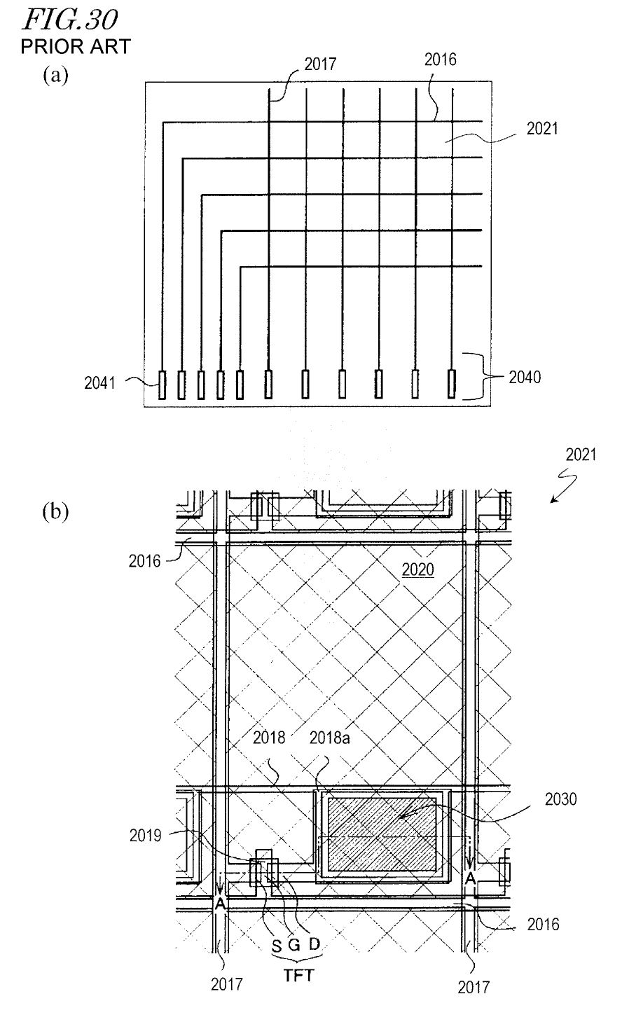

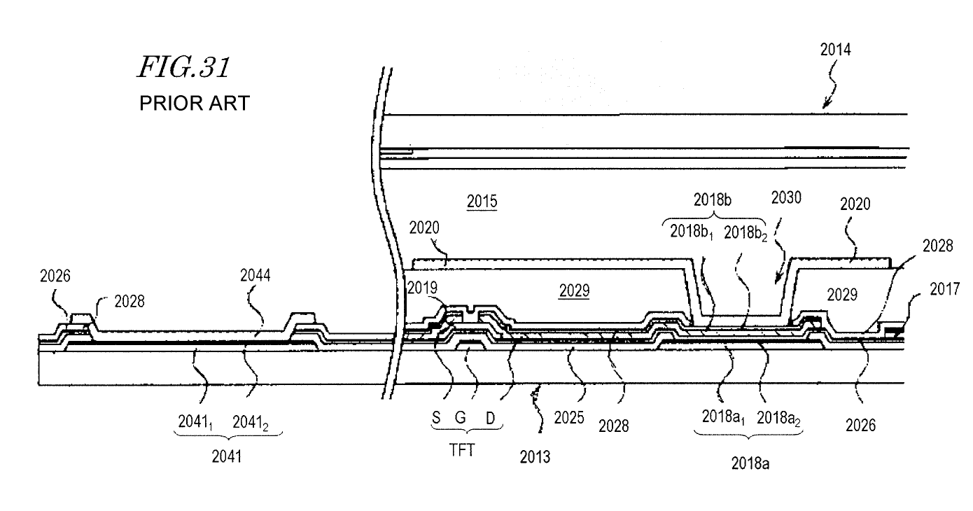

FIG. 29 is a cross-sectional view schematically illustrating a configuration for the organic EL display device 1002 (which will be sometimes simply referred to herein as a “display device 1002”). As shown in FIG. 29, the display device 1002 includes a TFT substrate 140, a hole transport layer 144 which is arranged on the TFT substrate 140, a light-emitting layer 146 which is stacked on the hole transport layer 144, and a counter electrode 148 which is arranged on the light-emitting layer 146. The hole transport layer 144 and the light-emitting layer 146 together form an organic EL layer, which is divided into multiple sections by insulating projections 147. Each divided section of the organic EL layer defines the organic EL layer of one pixel.

The TFT substrate 140 has basically the same configuration as the TFT substrate 100 according to any of the embodiments described above, and includes a TFT 10 which has been formed on the substrate 60. The TFT 10 may be a TFT according to any of the first through thirteenth embodiments described above. The TFT substrate 140 includes an interlayer insulating layer 74 which has been deposited over the TFTs 10 and a pixel electrode 109 which has been formed on the interlayer insulating layer 74. The pixel electrode 109 is connected to the drain electrode of the TFT 10 inside a contact hole which has been cut through the interlayer insulating layer 74. The layout of the TFT substrate 140 is basically the same as what is shown in FIGS. 2 and 3, and its description will be omitted herein. Optionally, a TFT substrate with no storage capacitors may also be used as the TFT substrate 140.

When a voltage is applied to the organic EL layer by the pixel electrode 109 and the counter electrode 148, the holes that have been generated from the pixel electrode 109 are sent to the light-emitting layer 146 via the hole transport layer 144. In the meantime, electrons which have been generated from the counter electrode 148 also move into the light-emitting layer 146. And those holes and electrons are recombined, thereby producing electroluminescence in the light-emitting layer 146. And by controlling the electroluminescence produced from the light-emitting layer 146 on a pixel-by-pixel basis using the TFT substrate 140 that is an active-matrix substrate, a display operation can be carried out just as intended.

The hole transport layer 144, the light-emitting layer 146 and the counter electrode 148 may be made of known materials and may have a known layered structure. Optionally, a hole injection layer may be provided between the hole transport layer 144 and the light-emitting layer 146 in order to increase the hole injection efficiency. To inject electrons into the organic EL layer highly efficiently while emitting the electroluminescence more efficiently, the counter electrode 148 is suitably made of a material that has high transmittance and a small work function.

The organic EL display device 1002 of this embodiment uses the TFT 10 that has been described for any of the first through thirteenth embodiments, and therefore, can achieve the same effects as what has already been described for the first through thirteenth embodiments. According to this embodiment, an organic EL display device 1002 which can conduct a high quality display operation can be provided with good productivity.

### INDUSTRIAL APPLICABILITY

The present invention can be used effectively in a semiconductor device with a thin-film transistor, a display device including a thin-film transistor on its TFT substrate, such as a liquid crystal display device and an organic EL display device.

### REFERENCE SIGNS LIST

10 TFT (thin-film transistor)
12 signal line
14 scan line
16 storage capacitor line
18 storage capacitor (Cs)
20 pixel electrode
20c storage capacitor counter electrode
20t, 22 conductive layer
25 connecting portion
30 terminal portion
50 pixel
60 substrate
62 gate electrode
62c storage capacitor electrode
62d lower wiring
66 gate insulating layer
68 oxide semiconductor layer
68m oxide semiconductor material
70d drain electrode
70s source electrode
70u upper wiring
72 protective layer
72h contact hole
74 oxygen supplying layer
78 anti-diffusion layer
90 common line
92 lower electrode
94 upper electrode
97 ES layer
100 TFT substrate (semiconductor device)
200 counter substrate
210, 220 polarizer
230 backlight unit
240 scan line driver
250 signal line driver
260 controller
1000 liquid crystal display device
1002 organic EL display device

1. (canceled)

2. A semiconductor device including a thin-film transistor, the device comprising:
a gate electrode which has been formed on a substrate as a part of the thin-film transistor;
a gate insulating layer which has been formed on the gate electrode;
an oxide semiconductor layer which has been formed on the gate insulating layer;
a source electrode and a drain electrode which are arranged on the oxide semiconductor layer as parts of the thin-film transistor;
a protective layer which has been formed on the oxide semiconductor layer and the source and drain electrodes;
an oxygen supplying layer which has been formed on the protective layer;
an anti-diffusion layer which has been formed on the oxygen supplying layer;
a lower wiring which is made of the same material as the gate electrode;
an upper wiring which is made of the same material as the source and drain electrodes; and
a connecting portion which connects the upper and lower wirings together,
wherein in the connecting portion, the upper and lower wirings are connected together through a contact hole which runs through the gate insulating layer.

3. The semiconductor device of claim 2, wherein the oxygen supplying layer is made of a material including water (H₂O), an OR group, or an OH group.

4. The semiconductor device of claim 2, wherein the oxygen supplying layer is made of an acrylic resin, an SOG material, a silicone resin, an ester polymer resin, or a resin including a silanol group, a CO—OR group or an Si—OH group.

5. The semiconductor device of claim 2, wherein the oxygen supplying layer has a thickness of 500 nm to 3500 nm.

6. The semiconductor device of claim 2, wherein the anti-diffusion layer is made of silicon dioxide, silicon nitride, or silicon oxynitride.

7. The semiconductor device of claim 2, wherein the anti-diffusion layer has a thickness of 50 nm to 500 nm.

8. The semiconductor device of claim 2, wherein the protective layer is made of silicon dioxide or silicon nitride.

9. The semiconductor device of claim 2, wherein in the connecting portion, the contact hole has been cut to run through the oxide semiconductor layer and the gate insulating layer, and the upper and lower wirings are connected together through the contact hole.

10. The semiconductor device of claim 2, wherein the connecting portion includes:
an insulating layer which has been formed on the lower wiring;
the upper wiring which has been formed on the insulating layer;
the protective layer which has been formed on the upper wiring;
the oxygen supplying layer which has been formed on the protective layer;
the anti-diffusion layer which has been formed on the oxygen supplying layer; and
a conductive layer which has been formed on the anti-diffusion layer, and
wherein a contact hole has been cut to run through the insulating layer, upper wiring, protective layer, oxygen supplying layer and anti-diffusion layer of the connecting portion, and
wherein the lower and upper wirings are electrically connected together through the conductive layer that has been deposited in the contact hole.

11. The semiconductor device of claim 2, wherein the connecting portion includes:
an insulating layer which has been formed on the lower wiring;
the upper wiring which has been formed on the insulating layer;
the protective layer which has been formed on the upper wiring;
the oxygen supplying layer which has been formed on the protective layer;
the anti-diffusion layer which has been formed on the oxygen supplying layer; and
a conductive layer which has been formed on the anti-diffusion layer, and
wherein a first contact hole has been cut to run through the protective layer, oxygen supplying layer and anti-diffusion layer of the connecting portion, and
wherein a second contact hole has been cut to run through the insulating layer, protective layer, oxygen supplying layer and anti-diffusion layer of the connecting portion, and
wherein the upper wiring and the conductive layer are electrically connected together inside the first contact hole, and
wherein the lower wiring and the conductive layer are electrically connected together inside the second contact hole.

12. The semiconductor device of claim 2, comprising a storage capacitor which includes:
a storage capacitor electrode which is made of the same material as the gate electrode;
the anti-diffusion layer which has been formed on and in contact with the storage capacitor electrode; and
a storage capacitor counter electrode which has been formed on the anti-diffusion layer.

13. The semiconductor device of claim 2, comprising a storage capacitor which includes:
a storage capacitor electrode which is made of the same material as the gate electrode;
a first conductive layer which has been formed on and in contact with the storage capacitor electrode;
the anti-diffusion layer which has been formed on and in contact with the first conductive layer; and
a storage capacitor counter electrode which has been formed on the anti-diffusion layer.

14. The semiconductor device of claim 2, comprising a storage capacitor which includes:
a storage capacitor electrode which is made of the same material as the gate electrode;
the oxide semiconductor layer which has been formed on and in contact with the storage capacitor electrode;
the anti-diffusion layer which has been formed on and in contact with the oxide semiconductor layer on the storage capacitor electrode; and
a storage capacitor counter electrode which has been formed on the anti-diffusion layer.

15. A display device comprising the semiconductor device of claim 2,
wherein the display device includes a pixel electrode which has been formed on the anti-diffusion layer, and
wherein the pixel electrode is connected to the drain electrode through a contact hole that runs through the protective layer, the oxygen supplying layer, and the anti-diffusion layer.

16. A fringe field type display device comprising the semiconductor device of claim 2,
wherein the display device includes:
a lower electrode which is arranged between the oxygen supplying layer and the anti-diffusion layer; and
an upper electrode which is arranged on the anti-diffusion layer and connected to the drain electrode of the thin-film transistor.

17. The fringe field type display device of claim 16, comprising a common line which is made of the same material as the gate electrode,
wherein the common line and the lower electrode are connected together through a contact hole that runs through the gate insulating layer, the protective layer, and the oxygen supplying layer.

18. An organic EL display device comprising the semiconductor device of claim 2.
